(19) United States
(12) Patent Application Publication
(10) Pub. No.: US 2025/0150059 A1
(43) Pub. Date: May 8, 2025

(54) ACOUSTIC WAVE ELEMENT, ACOUSTIC WAVE FILTER DEVICE, AND MULTIPLEXER

(71) Applicant: Murata Manufacturing Co., Ltd., Nagaokakyo-shi (JP)

(72) Inventor: Hidetaro NAKAZAWA, Nagaokakyo-shi (JP)

(21) Appl. No.: 18/921,188

(22) Filed: Oct. 21, 2024

(30) Foreign Application Priority Data
Nov. 8, 2023 (JP) 2023-191064

(51) Int. Cl. H03H 9/64; H03H 9/02; H03H 9/25

(52) U.S. Cl. CPC H03H 9/6496; H03H 9/02818; H03H 9/25; H03H 9/6483

(57) ABSTRACT

An acoustic wave element includes a first IDT electrode and first reflectors on a first main surface of a piezoelectric layer and a second IDT electrode and second reflectors on a second main surface of the piezoelectric layer. When a region between the first reflectors in a first direction is a first region, a region between the second reflectors in the first direction is a second region, and a minimum region including the first and second regions as viewed in a third direction orthogonal or substantially orthogonal to the first and second directions is an inter-reflector region, in an end region of the inter-reflector region in the first direction, a region is provided in which none of the first and second electrode fingers face each other in the third direction.

### CROSS REFERENCE TO RELATED APPLICATIONS

This application claims the benefit of priority to Japanese Patent Application No. 2023-191064 filed on Nov. 8, 2023. The entire contents of this application are hereby incorporated herein by reference.

### BACKGROUND OF THE INVENTION

### 1. Field of the Invention

The present invention relates to acoustic wave elements, acoustic wave filter devices, and multiplexers.

### 2. Description of the Related Art

In recent years, multi-band systems have been used to improve the data transmission speed of mobile phones. In this case, a plurality of filter devices through which high-frequency signals in different frequency bands pass are disposed in the front-end circuit of such a mobile phone because the transmission and reception of a plurality of frequency bands are required. In this case, high isolation with adjacent bands is required for the plurality of filter devices described above.

Japanese Unexamined Patent Application Publication No. 2005-217818 discloses a piezoelectric vibrator in which acoustic waves are confined in a portion of a piezoelectric structure. Japanese Unexamined Patent Application Publication No. 2005-217818 discloses, in FIG. 9, an acoustic wave element including a piezoelectric layer, an IDT electrode and a reflector formed on the front surface of the piezoelectric layer and an IDT electrode and a reflector formed on the back surface, as an example of the piezoelectric vibrator.

The acoustic wave element described in Japanese Unexamined Patent Application Publication No. 2005-217818 has a problem in that ripples occur at frequencies higher than the anti-resonance frequency of the acoustic wave element.

### SUMMARY OF THE INVENTION

Example embodiments of the present invention provide acoustic wave elements that are each able to reduce or prevent ripples from occurring at frequencies higher than an anti-resonance frequency.

An acoustic wave element according to an example embodiment of the present invention includes a piezoelectric layer, a first IDT electrode and a plurality of first reflectors on a first main surface of the piezoelectric layer, and a second IDT electrode and a plurality of second reflectors on a second main surface of the piezoelectric layer. The second main surface faces away from the first main surface. The first IDT electrode includes a plurality of first electrode fingers extending in a second direction crossing a first direction in a direction along the first main surface. The plurality of first reflectors are on both outer sides of the first IDT electrode in the first direction. Each of the plurality of first reflectors includes a plurality of first reflective electrode fingers extending in the second direction. The second IDT electrode includes a plurality of second electrode fingers extending in the second direction crossing the first direction in a direction along the second main surface. The plurality of second reflectors are on both outer sides of the second IDT electrode in the first direction. Each of the plurality of second reflectors include a plurality of second reflective electrode fingers extending in the second direction. When a region between the plurality of first reflectors in the first direction is a first region, a region between the plurality of second reflectors in the first direction is a second region, and a minimum region including the first region and the second region as viewed in a third direction orthogonal or substantially orthogonal to the first direction and the second direction is an inter-reflector region, in an end region of the inter-reflector region in the first direction, a region is provided in which none of the first electrode fingers and the second electrode fingers face each other in the third direction, or, in the end region of the inter-reflector region in the first direction, a region is provided in which none of the first reflective electrode fingers and the second reflective electrode fingers face each other in the third direction. An acoustic wave filter device according to an example embodiment of the present invention includes an acoustic wave element according to an example embodiment of the present invention.

A multiplexer according to an example embodiment of the present invention includes a plurality of filters including an acoustic wave filter device according to an example embodiment of the present invention, in which one of input/output terminals of the plurality of filters is directly or indirectly connected to a common terminal, and at least one of the plurality of filters excluding the acoustic wave filter device has a passband higher than a frequency in the passband of the acoustic wave filter device.

The acoustic wave elements according to example embodiments of the present invention are each able to reduce or prevent ripples from occurring at frequencies higher than the anti-resonance frequency.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a top view of a first IDT electrode and first reflectors of an acoustic wave element according to a first example embodiment of the present invention.

FIG. 1B is a top view of a second IDT electrode and second reflectors of the acoustic wave element according to the first example embodiment of the present invention.

FIG. 2 is a cross-sectional view of the acoustic wave element illustrated in FIGS. 1A and 1B taken along line II-II.

FIG. 3 is a cross-sectional view of the acoustic wave element illustrated in FIGS. 1A and 1B taken along line III-III.

FIG. 4A is a top view of a first IDT electrode and first reflectors of an acoustic wave element according to a comparative example.

FIG. 4B is a top view of a second IDT electrode and second reflectors of the acoustic wave element according to the comparative example.

FIG. 5 is a cross-sectional view of the acoustic wave element illustrated in FIG. 4A and FIG. 4B taken along line V-V.

FIG. 6A is a graph illustrating phase characteristics of the acoustic wave elements according to first to fourth examples and the comparative example.

FIG. 6B is an enlarged view of a VIB portion in FIG. 6A.

FIG. 6C is an enlarged view of a VIC portion in FIG. 6A.

FIG. 7A is a top view of a first IDT electrode and first reflectors of an acoustic wave element according to a first modification of the first example embodiment of the present invention.

FIG. 7B is a top view of a second IDT electrode and second reflectors of the acoustic wave element according to the first modification of the first example embodiment of the present invention.

FIG. 8 is a cross-sectional view of the acoustic wave element illustrated in FIGS. 7A and 7B taken along line VIII-VIII.

FIG. 9A is a top view of a first IDT electrode and a first reflector of an acoustic wave element according to a second modification of the first example embodiment of the present invention.

FIG. 9B is a top view of a second IDT electrode and second reflectors of the acoustic wave element according to the second modification of the first example embodiment of the present invention.

FIG. 10 is a cross-sectional view of the acoustic wave element illustrated in FIGS. 9A and 9B taken along line X-X.

FIG. 11A is a top view of a first IDT electrode and first reflectors of an acoustic wave element according to a third modification of the first example embodiment of the present invention.

FIG. 11B is a top view of a second IDT electrode and second reflectors of the acoustic wave element according to the third modification of the first example embodiment of the present invention.

FIG. 12 is a cross-sectional view of the acoustic wave element illustrated in FIGS. 11A and 11B taken along line XII-XII.

FIG. 13A is a top view of a first IDT electrode and first reflectors of an acoustic wave element according to a fourth modification of the first example embodiment of the present invention.

FIG. 13B is a top view of a second IDT electrode and second reflectors of the acoustic wave element according to the fourth modification of the first example embodiment of the present invention.

FIG. 14 is a cross-sectional view of the acoustic wave element illustrated in FIGS. 13A and 13B taken along line XIV-XIV.

FIG. 15A is a top view of a first IDT electrode and first reflectors of an acoustic wave element according to a fifth modification of the first example embodiment.

FIG. 15B is a top view of a second IDT electrode and second reflectors of the acoustic wave element according to the fifth modification of the first example embodiment of the present invention.

FIG. 16 is a cross-sectional view of the acoustic wave element illustrated in FIGS. 15A and 15B taken along line XVI-XVI.

FIG. 17 is a diagram illustrating a circuit structure of an acoustic wave filter device according to a second example embodiment of the present invention.

FIG. 18 is a circuit structure diagram of a multiplexer and its peripheral circuits according to a third example embodiment of the present invention.

### DETAILED DESCRIPTION OF THE EXAMPLE EMBODIMENTS

Example embodiments of the present invention will be described in detail below with reference to the drawings and tables. The example embodiments described below are all intended to be inclusive or specific examples. The values, shapes, materials, components, arrangement and connection configurations of components illustrated in the following examples are only illustrative and do not limit the scope of the present invention. Of the components described in the following examples, components not described in the independent claims will be described as optional components. In addition, the size or the size ratio of each of components in the drawings is not necessarily exact.

### First Example Embodiment

### Structure of Acoustic Wave Element

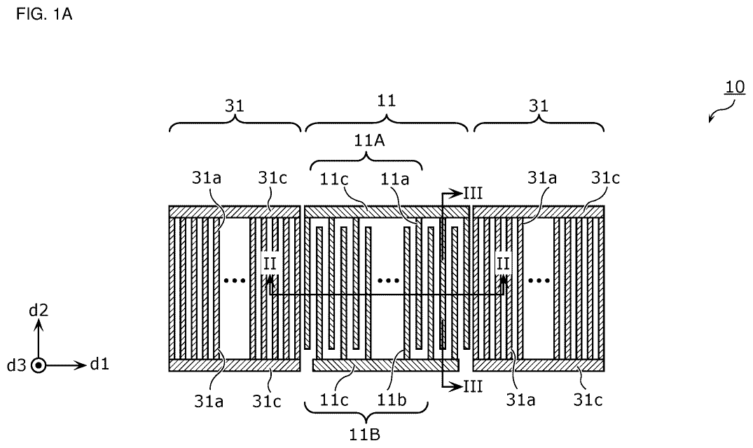

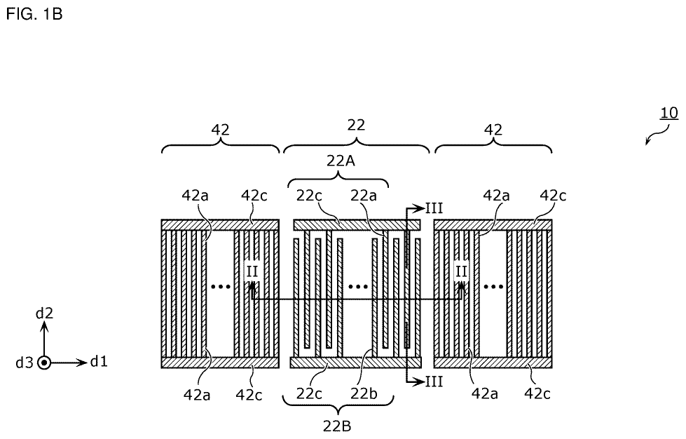

The structure of an acoustic wave element according to a first example embodiment of the present invention will be described with reference to FIGS. 1A to 3.

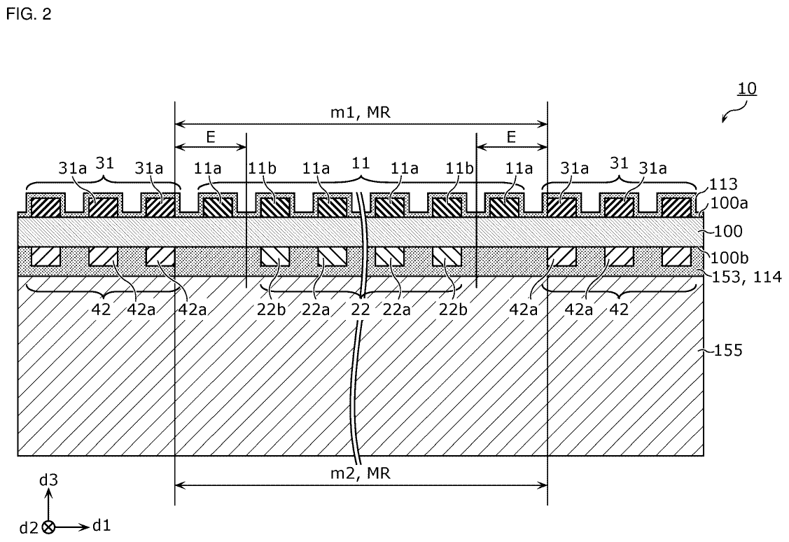

FIG. 1A is a top view of a first IDT electrode 11 and first reflectors 31 of an acoustic wave element 10 according to the first example embodiment. FIG. 1B is a top view of a second IDT electrode 22 and second reflectors 42 of the acoustic wave element 10. FIG. 2 is a cross-sectional view of the acoustic wave element 10 illustrated in FIGS. 1A and 1B taken along line II-II.

The acoustic wave element 10 illustrated in FIGS. 1A, 1B, and 2 is, for example, a one-port surface acoustic wave (SAW) resonator including a piezoelectric layer 100, a plurality of interdigital transducer (IDT) electrodes, and a plurality of reflectors.

The piezoelectric layer 100 illustrated in FIG. 2 includes, for example, a 0° rotated Y-cut X-propagating LiNbO₃ piezoelectric single crystal or piezoelectric ceramic (a lithium niobate single crystal or ceramic cut by a surface normal to the axis obtained by rotating θ° from the Y-axis to the Z-axis about the X-axis as the central axis in which surface acoustic waves propagates in the X-axis direction).

The piezoelectric layer 100 includes a first main surface 100a and a second main surface 100b. The first main surface 100a and the second main surface 100b, which are both main surfaces of the piezoelectric layer 100, face away from each other. The thickness of the piezoelectric layer 100 is equal to or smaller than the IDT wavelength (λ_{IDT}) described later.

The plurality of IDT electrodes include the first IDT electrode 11 and the second IDT electrode 22. The first IDT electrode 11 is provided on the first main surface 100a of the piezoelectric layer 100, and the second IDT electrode 22 is provided on the second main surface 100b of the piezoelectric layer 100. That is, the IDT electrodes are provided on both main surfaces of the piezoelectric layer 100.

The plurality of reflectors include the plurality of first reflectors 31 and the plurality of second reflectors 42. The plurality of first reflectors 31 are provided on the first main surface 100a of the piezoelectric layer 100, and the plurality of second reflectors 42 are provided on the second main surface 100b of the piezoelectric layer 100. In this example, the two reflectors are provided on both main surfaces of the piezoelectric layer 100.

FIGS. 1A and 1B are perspective views of the IDT electrodes and the reflectors as viewed in a direction orthogonal or substantially orthogonal to the main surfaces of the piezoelectric layer 100. As illustrated in FIG. 1A, the electrodes of the first reflectors 31 are disposed on both outer sides of the first IDT electrode 11 in a first direction d1 in which acoustic waves propagate. As illustrated in FIG. 1B, the electrodes of the second reflectors 42 are disposed on both outer sides of the second IDT electrode 22 in the first direction d1.

As illustrated in FIG. 2, the acoustic wave element 10 has a structure including the piezoelectric layer 100 and electrode layers 110a and 110b that define the IDT electrodes and the electrodes of the reflectors.

The electrode layers 110a and 110b have a laminated structure in which a plurality of metals are laminated together. For example, the electrode layer 110a that defines the first IDT electrode 11 and the electrodes of the first reflectors 31 has a laminated structure in which Ti, AlCu (Al including about 1% Cu), and Ti are laminated together in this order. The electrode layer 110b that defines the second IDT electrode 22 and the electrodes of the second reflectors 42 has, for example, a laminated structure in which Ti, Pt, and Ti are laminated together in this order. In this example, the thickness of the electrode layer 110b is smaller than that of the electrode layer 110a. In addition, the density of the electrode layer 110b is higher than that of the electrode layer 110a.

The materials constituting the electrode layers 110a and 110b are not limited to those described above. In addition, the laminated structures of the electrode layers 110a and 110b need not be the laminated structures described above. The electrode layers 110a and 110b may include, for example, metals, such as Ti, Al, Cu, Pt, Au, Ag, and Pd or alloys of these metals or may include a plurality of laminated bodies including metals, such as Ti, Al, Cu, Pt, Au, Ag, and Pd or alloys of these metals. Ti included in the electrode layers 110a and 110b improves adhesion with other layers.

In addition, the acoustic wave element 10 has a structure including a first insulating layer 113 provided closer to the first main surface 100a, and a low-acoustic-velocity layer 153 and a high-acoustic-velocity support substrate 155 provided closer to the second main surface 100b. The first insulating layer 113 is provided on the first main surface 100a of the piezoelectric layer 100 so as to cover the electrode layer 110a. That is, the first insulating layer 113 is provided on the first main surface 100a so as to cover first electrode fingers 11a and 11b of the first IDT electrode 11 and first reflective electrode fingers 31a of the first reflectors 31. The first insulating layer 113 protects the electrode layer 110a from the external environment, adjusts frequency-temperature characteristics, and improves moisture resistance and is a film that mainly includes, for example, silicon dioxide (SiO₂). The first insulating layer 113 need not necessarily be provided.

The low-acoustic-velocity layer 153 is provided on the second main surface 100b of the piezoelectric layer 100 so as to cover the electrode layer 110b. The low-acoustic-velocity layer 153 is an example of the second insulating layer 114. The low-acoustic-velocity layer 153 is provided on the second main surface 100b so as to cover second electrode fingers 22a and 22b of the second IDT electrode 22 and second reflective electrode fingers 42a of the second reflectors 42.

The second IDT electrode 22 and the electrode layer 110b defining the electrodes of the second reflectors 42 are embedded in the low-acoustic-velocity layer 153. The low-acoustic-velocity layer 153 is a film through which bulk waves propagate at an acoustic velocity lower than the acoustic velocity of acoustic waves propagating through the piezoelectric layer 100 and is disposed between the piezoelectric layer 100 and the high-acoustic-velocity support substrate 155. This structure and the property that causes energy to concentrate on a medium through which acoustic waves propagate at an inherently low-speed reduce or prevent surface acoustic wave energy from leaking to the outside of the IDT electrode. The low-acoustic-velocity layer 153 is a film mainly including, for example, silicon dioxide (SiO₂).

The material of the low-acoustic-velocity layer 153 may be, for example, a dielectric material, such as glass, silicon oxide, silicon oxynitride, lithium oxide, tantalum oxide, or compounds provided by adding fluorine, carbon, or boron to silicon oxide, or a material mainly including the materials described above.

The high-acoustic-velocity support substrate 155 supports the low-acoustic-velocity layer 153, the piezoelectric layer 100, and the electrode layers 110a and 110b. The high-acoustic-velocity support substrate 155 is a substrate through which bulk waves propagate at an acoustic velocity higher than the acoustic velocity of acoustic waves of surface waves or boundary waves propagating through the piezoelectric layer 100 and functions to prevent surface acoustic waves from leaking downward from the high-acoustic-velocity support substrate 155 by confining the surface acoustic waves in the portion in which the piezoelectric layer 100 and the low-acoustic-velocity layer 153 are laminated together. The high-acoustic-velocity support substrate 155 is, for example, a silicon substrate.

The material of the high-acoustic-velocity support substrate 155 may be, for example, a piezoelectric substance such as aluminum nitride, lithium tantalate, lithium niobate, quartz, a ceramic such as alumina, sapphire, magnesia, silicon nitride, silicon carbide, zirconia, cordierite, mullite, steatite, forsterite, spinel, or sialon, a dielectric material such as aluminum oxide, silicon oxynitride, DLC (diamond-like carbon), diamond, or a semiconductor such as silicon, or a material mainly containing the materials described above. The spinel described above includes, for example, an aluminum compound that includes oxygen and one or more elements selected from Mg, Fe, Zn, Mn, and the like. An example of the spinel described above may be MgAl₂O₄, FeAl₂O₄, ZnAl₂O₄, or MnAl₂O₄.

The high-acoustic-velocity support substrate 155 may have a structure in which the support substrate and a high-acoustic-velocity layer through which bulk waves propagate at an acoustic velocity higher than the acoustic velocity of acoustic waves of surface waves or boundary waves propagating through the piezoelectric layer 100 are laminated together.

In this case, the material of the support substrate may be, for example, a piezoelectric substance such as aluminum nitride, lithium tantalate, lithium niobate, quartz, a ceramic such as alumina, sapphire, magnesia, silicon nitride, silicon carbide, zirconia, cordierite, steatite, mullite, or forsterite, a dielectric material such as diamond or glass, or a semiconductor such as silicon or gallium nitride, a resin, or a material mainly containing the materials described above. In addition, the material of the high-acoustic-velocity layer may be various high-acoustic-velocity materials, such as, for example, aluminum nitride, aluminum oxide, silicon carbide, silicon nitride, silicon oxynitride, a DLC film, or diamond, a medium mainly including the materials described above, or a medium mainly including mixtures of the materials described above.

The laminated structure of the piezoelectric layer 100 can significantly increase the Q value of the acoustic wave element at the resonance frequency and the anti-resonance frequency as compared with the structure using the piezoelectric layer as a single layer. That is, since a surface acoustic wave resonator having a high Q value can be achieved, a filter with low insertion loss can be achieved by using the surface acoustic wave resonator.

In addition, the piezoelectric layer 100 is supported by the low-acoustic-velocity layer 153 even in a portion in which acoustic waves are excited because the second IDT electrode 22 is embedded in the low-acoustic-velocity layer 153, and accordingly, the shape of the piezoelectric layer 100 is not easily deformed, and electrical characteristics can be reduced or prevented from fluctuating. Furthermore, since the second IDT electrode 22 is embedded in the low-acoustic-velocity layer 153, higher-order modes can leak toward the low-acoustic-velocity layer 153. This can reduce or prevent generation of higher-order modes.

In the following description, the direction of propagation of acoustic waves along the main surface of the piezoelectric layer 100 is a first direction d1, the direction along the main surface of the piezoelectric layer 100 and in which the electrode fingers of the IDT electrode extend is a second direction d2, and the direction orthogonal or substantially orthogonal to both the first direction d1 and the second direction d2 is a third direction d3. The second direction d2 crosses the first direction d1, and the third direction d3 is orthogonal or substantially orthogonal to the piezoelectric layer 100.

As illustrated in FIG. 1A, the first IDT electrode 11 includes a pair of interdigital electrodes 11A and 11B facing each other. One interdigital electrode 11A includes the plurality of first electrode fingers 11a extending in the second direction d2 and a busbar electrode 11c that connects ends of the plurality of first electrode fingers 11a to each other. The other interdigital electrode 11B includes the plurality of first electrode fingers 11b extending in the second direction d2 and the busbar electrode 11c connecting ends of the plurality of first electrode fingers 11b to each other. The plurality of first electrode fingers 11a and 11b are arranged at a predetermined pitch in the first direction d1.

The first reflector 31 is disposed adjacent to the first IDT electrode 11 in the first direction d1. The first reflector 31 includes the plurality of first reflective electrode fingers 31a extending in the second direction d2 and a busbar electrode 31c connecting ends of the plurality of first reflective electrode fingers 31a to each other. The plurality of first reflective electrode fingers 31a are arranged at a predetermined pitch in the first direction d1.

As illustrated in FIG. 1B, the second IDT electrode 22 includes a pair of interdigital electrodes 22A and 22B that face each other. One interdigital electrode 22A includes the plurality of second electrode fingers 22a extending in the second direction d2 and a busbar electrode 22c connecting ends of the plurality of second electrode fingers 22a to each other. The other interdigital electrode 22B includes the plurality of second electrode fingers 22b extending in the second direction d2 and the busbar electrode 22c connecting ends of the plurality of second electrode fingers 22b to each other. The plurality of second electrode fingers 22a and 22b are arranged at a predetermined pitch in the first direction d1.

The second reflector 42 is disposed adjacent to the second IDT electrode 22 in the first direction d1. The second reflector 42 includes the plurality of second reflective electrode fingers 42a extending in the second direction d2 and a busbar electrode 42c connecting ends of the plurality of second reflective electrode fingers 42a to each other. The plurality of second reflective electrode fingers 42a are arranged at a predetermined pitch in the first direction d1.

The first electrode fingers 11a and the second electrode fingers 22a disposed vertically on both sides of the piezoelectric layer 100 have the same polarity, and the first electrode fingers 11b and the second electrode fingers 22b disposed vertically also have the same polarity.

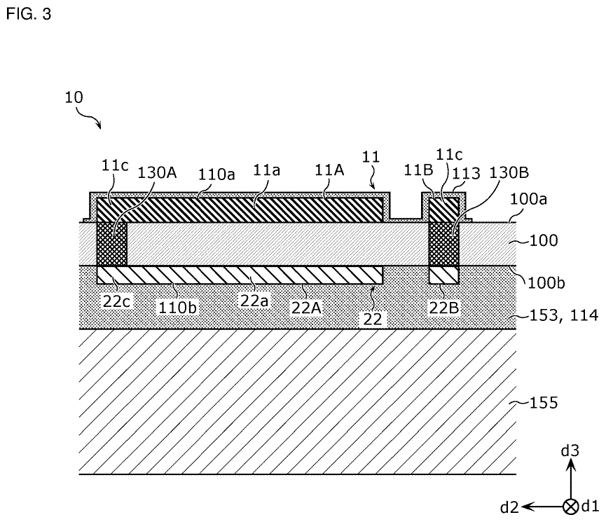

FIG. 3 is a cross-sectional view of the acoustic wave element 10 illustrated in FIGS. 1A and 1B taken along line III-III.

As illustrated in FIG. 3, the first IDT electrode 11 and the second IDT electrode 22 of the acoustic wave element 10 are connected to each other.

For example, one interdigital electrode 11A included in the first IDT electrode 11 and one interdigital electrode 22A included in the second IDT electrode 22 are electrically connected to each other. Specifically, the busbar electrode 11c of one interdigital electrode 11A and the busbar electrode 22c of the other interdigital electrode 22A are connected to each other by one via conductor 130A penetrating the piezoelectric layer 100 in the thickness direction.

In addition, the other interdigital electrode 11B included in the first IDT electrode 11 and the other interdigital electrode 22B included in the second IDT electrode 22 are electrically connected to each other. Specifically, the busbar electrode 11c of the other interdigital electrode 11B and the busbar electrode 22c of the other interdigital electrode 22B are connected to each other by one via conductor 130B penetrating the piezoelectric layer 100 in the thickness direction.

The two interdigital electrodes disposed vertically on both sides of the piezoelectric layer 100 may be electrically connected to each other at positions at which the busbar electrodes are provided or may be electrically connected to each other at positions of lead lines that lead to the busbar electrodes. In addition, the first reflector 31 and the second reflector 42 disposed vertically on both sides of the piezoelectric layer 100 are not connected to each other by a via conductor or the like but may be set to the reference potential (ground).

In the present example embodiment, the shape of the first IDT electrode 11 is the same or almost the same as the shape of the second IDT electrode 22, but the first electrode finger in the end portion of the first IDT electrode 11 does not face the second electrode finger in the end portion of the second IDT electrode 22.

Here, as illustrated in FIG. 2, when a region between the plurality of first reflectors 31 in the first direction d1 is defined as a first region m1, a region between the plurality of second reflectors 42 in the first direction d1 is defined as a second region m2, and a minimum region including the first region m1 and the second region m2 as viewed in the third direction d3 is defined as an inter-reflector region MR.

The minimum region that includes the first region m1 and the second region m2 is a region obtained by adding, to the region in which there are both the first region m1 and the second region m2 as viewed in the third direction d3, the region in which there is only one of these regions if there is the region in which there is only one of these regions. If there is not the region in which there is only one of these regions, the minimum region that contains the first region m1 and the second region m2 is the region in which both the first region m1 and the second region m2 are present. In this example, the first region m1, the second region m2, and the inter-reflector region MR are the same region in the first direction d1.

As illustrated in FIG. 2, in one end region E (for example, the end region in the negative first direction d1) of the inter-reflector region MR in the first direction d1, the first electrode finger 11a is disposed on the first main surface 100a, but no electrode finger is disposed on the second main surface 100b. In this example, in a region, on the second main surface 100b, that is located in the third direction d3 as viewed from the first electrode finger 11a located in one end region E, no second electrode finger is disposed and the second insulating layer 114 is provided.

In addition, as illustrated in FIG. 2, in the other end region E (for example, the end region in the positive first direction d1) of the inter-reflector region MR in the first direction d1, the first electrode finger 11a is disposed on the first main surface 100a, but no electrode finger is disposed on the second main surface 100b. In this example, in a region, on the second main surface 100b, that is located in the third direction d3 as viewed from the first electrode finger 11a located in the other end region E, no second electrode finger is disposed and the second insulating layer 114 is provided.

That is, in one end region E and the other end region E of the inter-reflector region MR in the first direction d1, the acoustic wave element 10 includes the regions in which none of the first electrode fingers 11a and 11b and the second electrode fingers 22a and 22b face each other in the third direction d3. The end region E refers to a region from an edge of the inter-reflector region MR in the first direction d1 to a portion a predetermined distance inside, and the predetermined distance is, for example, about 10% of the length of the inter-reflector region MR in the first direction d1.

The first electrode finger that does not face the second electrode finger in each of the end regions E includes at least the first electrode finger closest to the first reflector 31 of the plurality of first electrode fingers 11a and 11b arranged in the first direction d1. One first electrode finger 11a that does not face the second electrode finger is illustrated in each of the end regions E in this drawing, but the number of first electrode fingers that do not face the second electrode fingers is not limited to one and may two or more.

For example, the number of first electrode fingers 11a and 11b and second electrode fingers 22a and 22b that do not face each other in each of the end regions E is preferably more than about 0% and not more than about 2.5% of the total number of first electrode fingers 11a and 11b and first reflective electrode fingers 31a. That is, for example, the number of first electrode fingers 11a and 11b and second electrode fingers 22a and 22b that do not face each other in both one end region E and the other end region E is preferably more than about 0% and not more than about 5% of the total number of first electrode fingers 11a and 11b and first reflective electrode fingers 31a.

For example, when the total number of first electrode fingers 11a and 11b and first reflective electrode fingers 31a is 222, the number of first electrode fingers 11a and 11b and second electrode fingers 22a and 22b that do not face each other in each of the end regions E may be 1, 2 or 5. The number of first electrode fingers 11a and 11b and second electrode fingers 22a and 22b that do not face each other in both one end region E and the other end region E may be, for example, 2, 4, or 10.

Since there are regions in which none of the first electrode fingers 11a and 11b and the second electrode fingers 22a and 22b face each other in the third direction d3 in the end regions E of the inter-reflector region MR in the first direction d1 as described above, ripples can be reduced or prevented from occurring at frequencies higher than the anti-resonance frequency of the acoustic wave element 10.

Phase Characteristics Etc. of Acoustic Wave Elements According to First to Fourth Examples and Comparative Example

The phase characteristics and the like of the acoustic wave elements 10 according to first to fourth examples, which are examples of the first example embodiment, and an acoustic wave element 510 according to a comparative example will be described.

For comparison with individual examples, the structure of the acoustic wave element 510 according to the comparative example will be described.

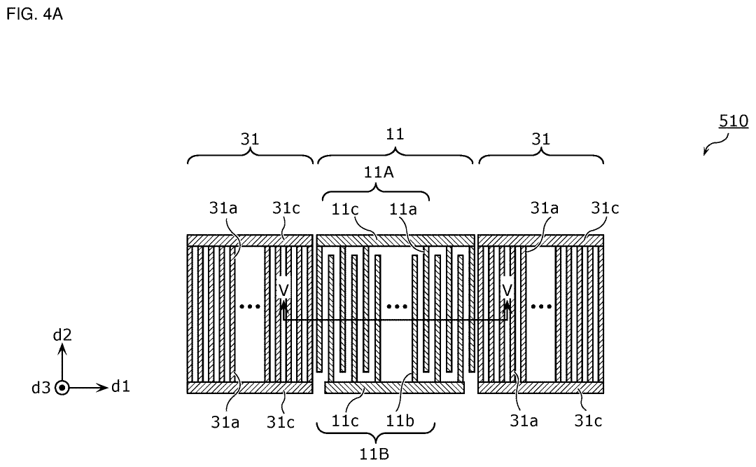

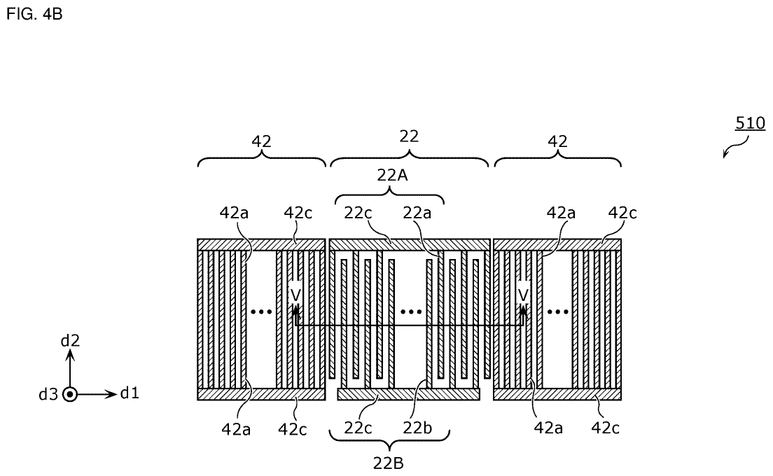

FIG. 4A is a top view of a first IDT electrode 11 and first reflectors 31 of the acoustic wave element 510 according to the comparative example. FIG. 4B is a top view of a second IDT electrode 22 and second reflectors 42 of the acoustic wave element 510.

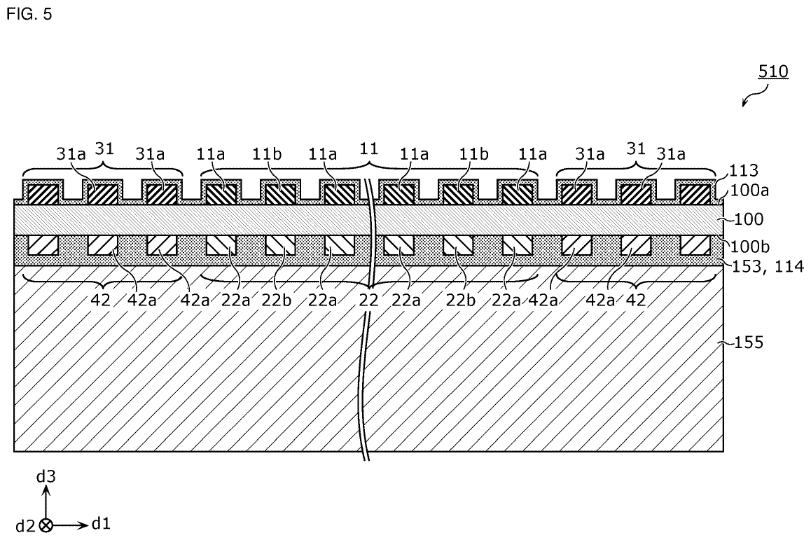

FIG. 5 is a cross-sectional view of the acoustic wave element 510 illustrated in FIG. 4A and FIG. 4B taken along line V-V.

The acoustic wave element 510 according to the comparative example includes the piezoelectric layer 100, the first IDT electrode 11, the plurality of first reflectors 31, the second IDT electrode 22, the plurality of second reflectors 42, the first insulating layer 113, the low-acoustic-velocity layer 153, and the high-acoustic-velocity support substrate 155.

In the acoustic wave element 510 according to the comparative example, as viewed in the third direction d3, the first IDT electrode 11 and the second IDT electrode 22 are disposed at the same or substantially the same position, and the first reflectors 31 and the second reflectors 42 are disposed at the same or substantially the same positions. In other words, as viewed in the third direction d3, the first IDT electrode 11 and the second IDT electrode 22 overlap each other, and the first reflectors 31 and the second reflectors 42 overlap each other.

On the other hand, in the acoustic wave elements 10 according to the first to fourth examples, as viewed in the third direction d3, the first IDT electrode 11 and the second IDT electrode 22 overlap each other except the end region E of the inter-reflector region MR and do not overlap each other in the end region E, and the first reflector 31 and the second reflector 42 overlap each other.

In the acoustic wave elements 10 according to first to fourth examples and the acoustic wave element 510 according to the comparative example, the wavelength λ_{IDT} of each of the first IDT electrode 11 and the second IDT electrode 22 is, for example, about 1 μm. Since the arrangement pitch of the electrode fingers arranged in the first direction d1 is about half the wavelength, the arrangement pitch of the first electrode fingers 11a and 11b, the arrangement pitch of the second electrode fingers 22a and 22b, the arrangement pitch of the first reflective electrode fingers 31a, and the arrangement pitch of the second reflective electrode fingers 42a are, for example, about 0.5 μm. For example, the thickness of the piezoelectric layer 100 is about 0.2λ_{IDT}, the thickness of the first IDT electrode 11 is about 0.015λ_{IDT}, and the thickness of the second IDT electrode 22 is about 0.018λ_{IDT}. The thickness of the first insulating layer 113 is about 0.015λ_{IDT}, the thickness of the low-acoustic-velocity layer 153 (second insulating layer 114) is about 0.218λ_{IDT}, and the thickness of the high-acoustic-velocity support substrate 155 about 0.45λ_{IDT}. The thickness of the low-acoustic-velocity layer 153 is the thickness at the point at which the second electrode fingers 22a and 22b of the second IDT electrode 22 are not provided, that is, at the point in contact with the second main surface 100b.

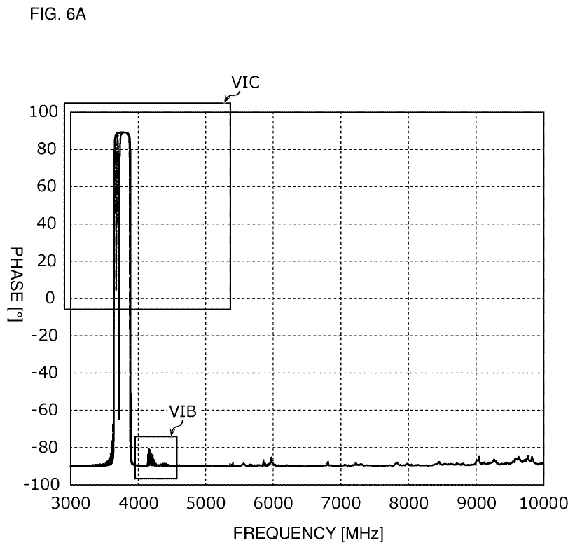

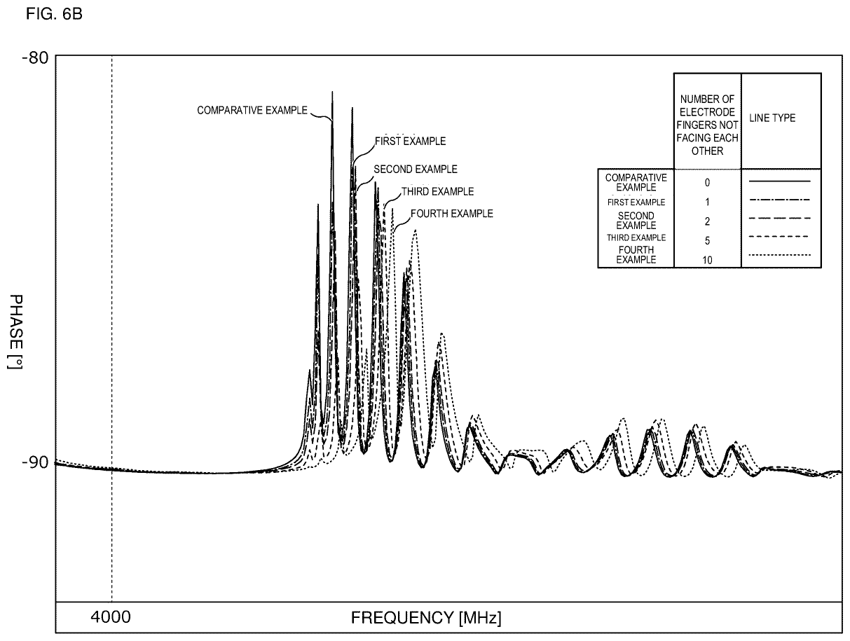

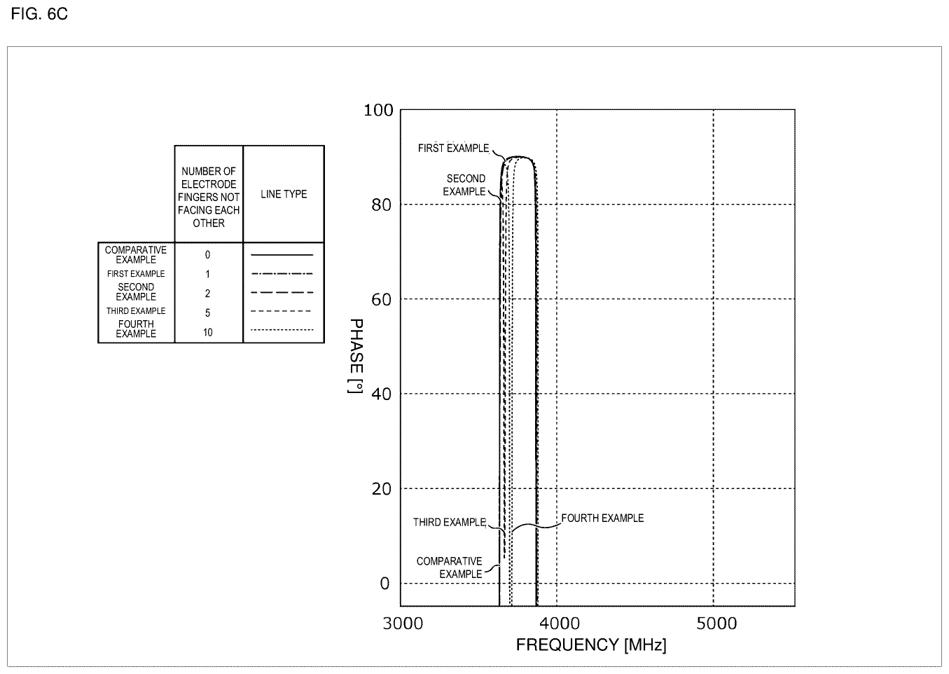

FIG. 6A is a graph illustrating phase characteristics of the acoustic wave elements according to the first to fourth examples and the comparative example. FIG. 6B is an enlarged view of a VIB portion in FIG. 6A. FIG. 6C is an enlarged view of a VIC portion in FIG. 6A.

FIG. 6A illustrates the phase characteristics when a high-frequency signal is input from the busbar electrode of one interdigital electrode of the acoustic wave element to the IDT electrode. In this case, the other interdigital electrode is short-circuited. In FIG. 6A, the region above 0 on the vertical axis indicates that the impedance of the acoustic wave element is inductive, and the region below 0 indicates that the impedance of the acoustic wave element is capacitive. In FIG. 6A, ripples that are unnecessary waves appear at frequencies higher than a band (band between the resonance frequency and the anti-resonance frequency) in which the impedance is inductive.

FIG. 6B is an enlarged view of the phase in a frequency band higher than a frequency band in which the impedance of the acoustic wave element is inductive. FIG. 6C is an enlarged view of the phase in a frequency band in which the impedance of the acoustic wave element is inductive. FIGS. 6A to 6C illustrate the number of first electrode fingers and second electrode fingers that do not face each other in one end region E.

Focusing on FIG. 6B, ripples that occur at frequencies higher than a frequency band in which the impedance is inductive in the acoustic wave elements 10 according to the first to fourth examples are smaller than those of the acoustic wave element according to the comparative example. In addition, as the number of electrode fingers that do not face each other increases in order of examples 1, 2, 3, and 4, ripples become smaller. The reason why ripples are reduced is considered to be because Bragg reflection by the reflectors is reduced or prevented as the number of electrode fingers that do not face each other increases. As described above, in the end regions E of the inter-reflector region MR in the first direction d1, by increasing the number of electrode fingers that do not face each other in the third direction d3, ripples can be reduced or prevented from occurring at frequencies higher than a band in which the impedance of the acoustic wave element 10 is inductive.

The phase value representing inductiveness is reduced in some frequency bands in the first to fourth examples illustrated in FIG. 6C, but this problem can be addressed by other methods. For example, by using the acoustic wave elements 10 according to the first to fourth examples as parallel arm resonators that define the low-frequency band of the passband of a ladder bandpass filter, the effect of changes in the phase representing inductiveness on the passband of the bandpass filter can be reduced. Even when the acoustic wave elements 10 are used as series arm resonators, the effect of changes in the phase representing inductiveness on the passband of the bandpass filter can be reduced by providing the passband including other series arm resonators.

### First Modification of First Example Embodiment

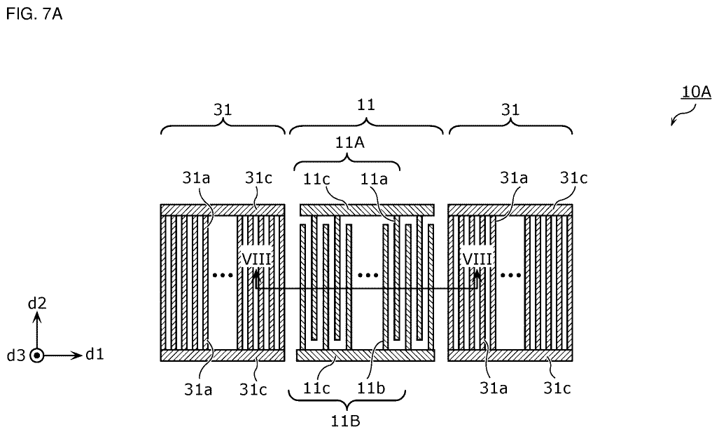

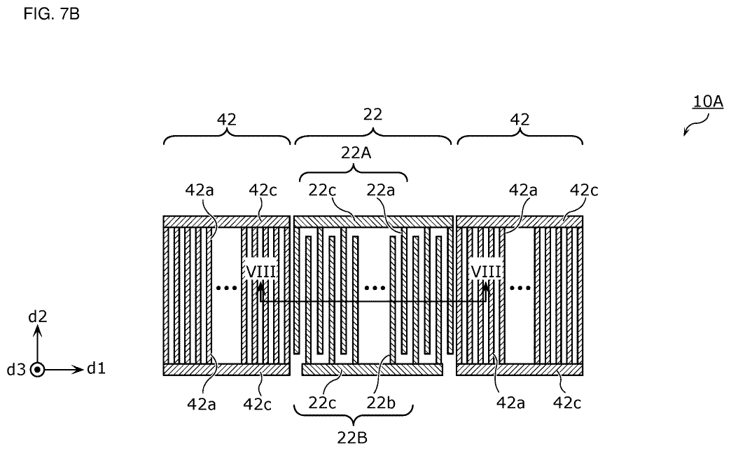

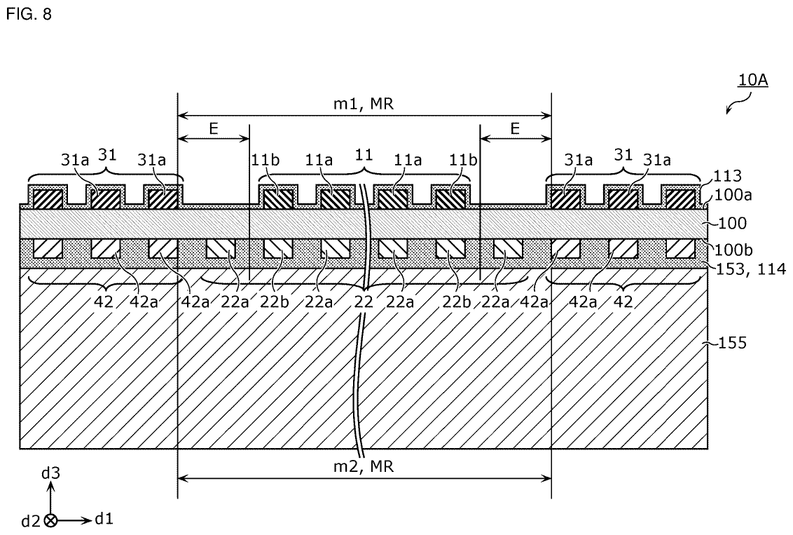

An acoustic wave element 10A according to a first modification of the first example embodiment will be described with reference to FIGS. 7A to 8. In the first modification, an example in which the second electrode fingers in the end portions of the second IDT electrode 22 do not face the first electrode fingers in the end portions of the first IDT electrode 11 will be described.

FIG. 7A is a top view of the first IDT electrode 11 and the first reflectors 31 of the acoustic wave element 10A according to the first modification of the first example embodiment. FIG. 7B is a top view of the second IDT electrode 22 and the second reflectors 42 of the acoustic wave element 10A. FIG. 8 is a cross-sectional view of the acoustic wave element 10A illustrated in FIGS. 7A and 7B taken along line VIII-VIII.

The acoustic wave element 10A illustrated in FIGS. 7A, 7B, and 8 includes the piezoelectric layer 100, the first IDT electrode 11, the plurality of first reflectors 31, the second IDT electrode 22, the plurality of second reflectors 42, the first insulating layer 113, the low-acoustic-velocity layer 153 (second insulating layer 114), and the high-acoustic-velocity support substrate 155. Also in this example, the first region m1, the second region m2, and the inter-reflector region MR are the same region in the first direction d1.

As illustrated in FIG. 8, in one end region E of the inter-reflector region MR in the first direction d1, the second electrode finger 22a is disposed on the second main surface 100b, but no electrode finger is disposed on the first main surface 100a. In this example, in a region, on the first main surface 100a, that is located in the third direction d3 as viewed from the second electrode finger 22a located in one end region E, no first electrode finger is disposed and the first insulating layer 113 is formed.

In addition, as illustrated in FIG. 8, in the other end region E of the inter-reflector region MR in the first direction d1, the second electrode finger 22a is disposed on the second main surface 100b, but no electrode finger is disposed on the first main surface 100a. In this example, in a region, on the first main surface 100a, that is located in the third direction d3 as viewed from the second electrode finger 22a located in the other end region E, no first electrode finger is disposed and the first insulating layer 113 is formed.

That is, in both of one end region E and the other end region E of the inter-reflector region MR in the first direction d1, the acoustic wave element 10A includes the regions in which none of the first electrode fingers 11a and 11b and the second electrode fingers 22a and 22b face each other in the third direction d3.

The second electrode finger that does not face the first electrode finger in each of the end regions E includes at least the second electrode finger closest to the second reflector 42 of the plurality of second electrode fingers 22a and 22b arranged in the first direction d1. One second electrode finger 22a that does not face the first electrode finger is illustrated in each of the end regions E in this drawing, but the number of second electrode fingers that do not face the first electrode fingers is not limited to one and may be two or more.

For example, the number of first electrode fingers 11a and 11b and second electrode fingers 22a and 22b that do not face each other in each of the end regions E is preferably more than about 0% and not more than about 2.5% of the total number of second electrode fingers 22a and 22b and second reflective electrode fingers 42a. That is, for example, the number of first electrode fingers 11a and 11b and second electrode fingers 22a and 22b that do not face each other in both one end region E and the other end region E is preferably more than about 0% and not more than about 5% of the total number of second electrode fingers 22a and 22b and second reflective electrode fingers 42a.

For example, when the total number of second electrode fingers 22a and 22b and second reflective electrode fingers 42a is 222, the number of first electrode fingers 11a and 11b and second electrode fingers 22a and 22b that do not face each other in each of the end regions E may be 1, 2, or 5. The number of first electrode fingers 11a and 11b and second electrode fingers 22a and 22b that do not face each other in both of one end region E and the other end region E may be, for example, 2, 4, or 10.

Since there are regions in which none of the first electrode fingers 11a and 11b and the second electrode fingers 22a and 22b face each other in the third direction d3 in the end regions E of the inter-reflector region MR in the first direction d1 as described above, ripples can be reduced or prevented from occurring at frequencies higher than the anti-resonance frequency of the acoustic wave element 10A.

### Second Modification of First Example Embodiment

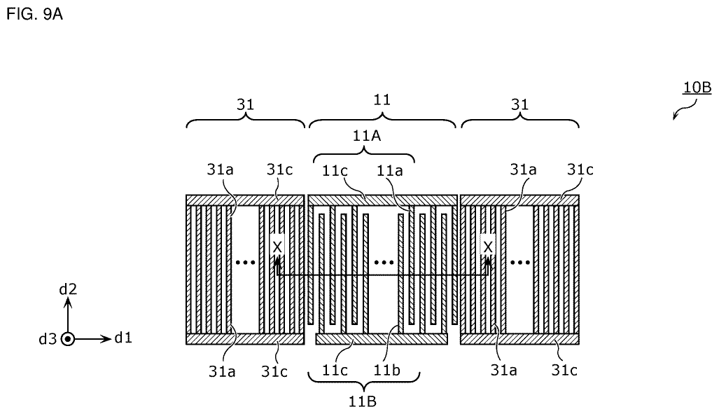

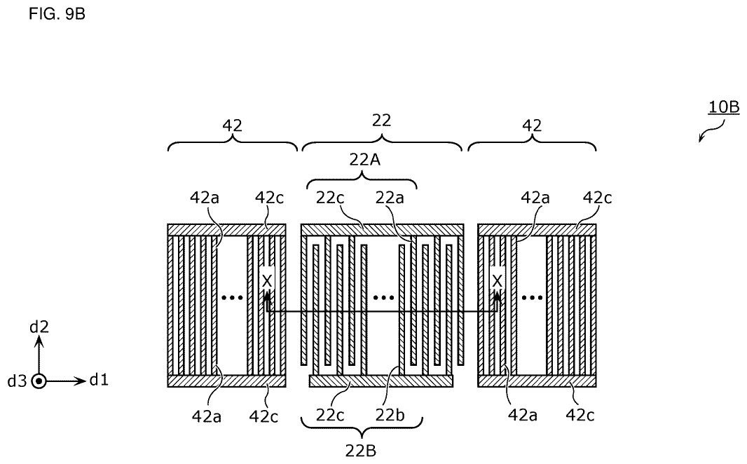

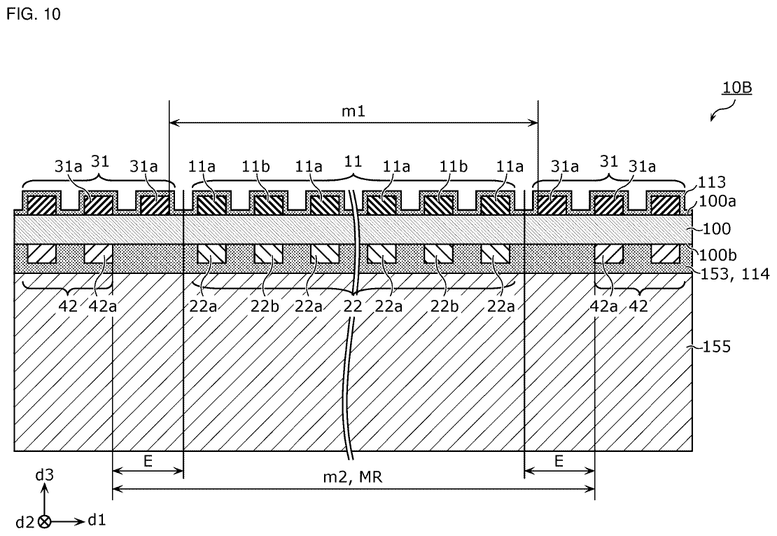

An acoustic wave element 10B according to a second modification of the first example embodiment will be described with reference to FIGS. 9A to 10. In the second modification, an example in which the first reflective electrode fingers in the end portions of the first reflectors 31 do not face the second reflective electrode fingers in the end portions of the second reflectors 42 will be described.

FIG. 9A is a top view of the first IDT electrode 11 and the first reflectors 31 of the acoustic wave element 10B according to the second modification of the first example embodiment. FIG. 9B is a top view of the second IDT electrode 22 and the second reflectors 42 of the acoustic wave element 10B. FIG. 10 is a cross-sectional view of the acoustic wave element 10B illustrated in FIGS. 9A and 9B taken along line X-X.

The acoustic wave element 10B illustrated in FIGS. 9A, 9B, and 10 includes the piezoelectric layer 100, the first IDT electrode 11, the plurality of first reflectors 31, the second IDT electrode 22, the plurality of second reflectors 42, the first insulating layer 113, the low-acoustic-velocity layer 153 (second insulating layer 114), and the high-acoustic-velocity support substrate 155. In this example, the second region m2 and the inter-reflector region MR are the same region in the first direction d1.

As illustrated in FIG. 10, in one end region E of the inter-reflector region MR in the first direction d1, the first reflective electrode finger 31a is disposed on the first main surface 100a, but no reflective electrode finger is disposed on the second main surface 100b. In this example, in a region, on the second main surface 100b, that is located in the third direction d3 as viewed from the first reflective electrode finger 31a located in one end region E, no second reflective electrode finger is disposed and the second insulating layer 114 is provided.

In addition, as illustrated in FIG. 10, in the other end region E of the inter-reflector region MR in the first direction d1, the first reflective electrode finger 31a is disposed on the first main surface 100a, but no reflective electrode finger is disposed on the second main surface 100b. In this example, in a region, on the second main surface 100b, that is located in the third direction d3 as viewed from the first reflective electrode finger 31a located in the other end region E, no second reflective electrode finger is disposed and the second insulating layer 114 is provided.

That is, in both of one end region E and the other end region E of the inter-reflector region MR in the first direction d1, the acoustic wave element 10B includes regions in which none of the first reflective electrode fingers 31a and the second reflective electrode fingers 42a face each other in the third direction d3.

The first reflective electrode finger that does not face the second reflective electrode finger in each of the end regions E includes at least the first reflective electrode finger closest to the first IDT electrode 11 of the plurality of first reflective electrode fingers 31a arranged in the first direction d1. One first reflective electrode finger 31a that does not face the second reflective electrode finger is illustrated in each of the end regions E in FIG. 10, but the number of first reflective electrode fingers that do not face the second reflective electrode fingers is not limited to one and may be, for example, two or more.

For example, the number of first reflective electrode fingers 31a and second reflective electrode fingers 42a that do not face each other in each of the end regions E is preferably more than about 0% and not more than about 2.5% of the total number of first electrode fingers 11a and 11b and first reflective electrode fingers 31a. That is, for example, the number of first the reflective electrode fingers 31a and second reflective electrode fingers 42a that do not face each other in both one end region E and the other end region E is preferably more than about 0% and not more than about 5% of the total number of first electrode fingers 11a and 11b and first reflective electrode fingers 31a.

For example, when the total number of first electrode fingers 11a and 11b and first reflective electrode fingers 31a is 222, the number of first reflective electrode fingers 31a and second reflective electrode fingers 42a that do not face each other in each of the end regions E may be 1, 2 or 5. The number of first reflective electrode fingers 31a and second reflective electrode fingers 42a that do not face each other in both one end region E and the other end region E may be, for example, 2, 4, or 10.

Since there are regions in which none of the first reflective electrode fingers 31a and the second reflective electrode fingers 42a face each other in the third direction d3 in the end regions E of the inter-reflector region MR in the first direction d1 as described above, ripples can be reduced or prevented from occurring at frequencies higher than the anti-resonance frequency of the acoustic wave element 10B.

### Third Modification of First Example Embodiment

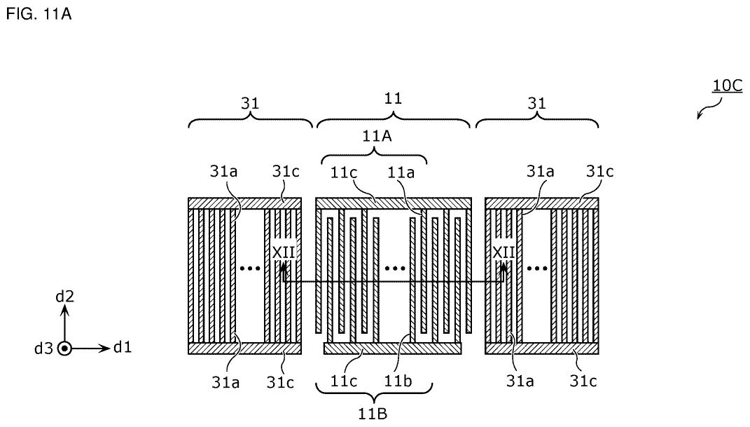

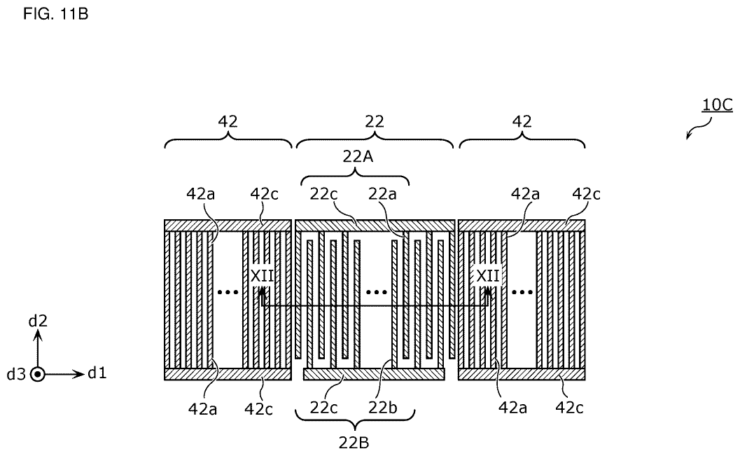

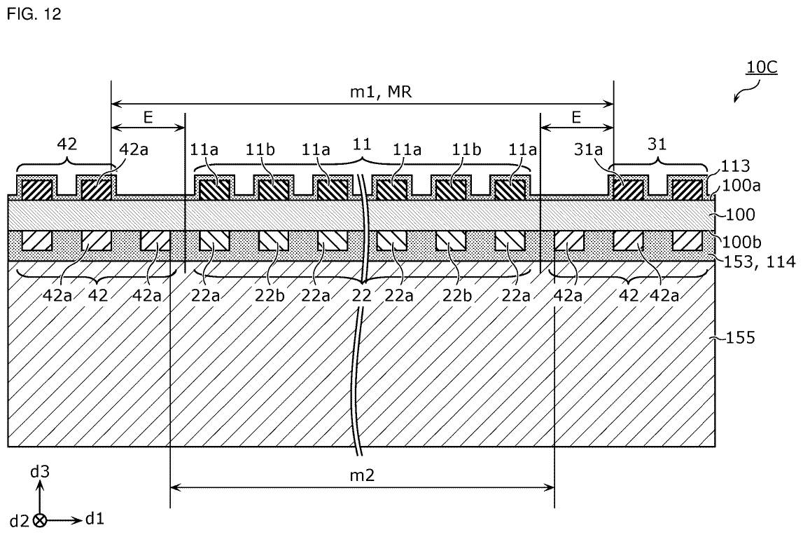

An acoustic wave element 10C according to a third modification of the first example embodiment will be described with reference to FIGS. 11A to 12. In the third modification, an example in which the second reflective electrode fingers in the end portions of the second reflectors 42 do not face the first reflective electrode finger in the end portion of the first reflector 31 will be described.

FIG. 11A is a top view of the first IDT electrode 11 and the first reflectors 31 of the acoustic wave element 10C according to the third modification of the first example embodiment. FIG. 11B is a top view of the second IDT electrode 22 and the second reflectors 42 of the acoustic wave element 10C. FIG. 12 is a cross-sectional view of the acoustic wave element 10C illustrated in FIGS. 11A and 11B taken along line XII-XII.

The acoustic wave element 10C illustrated in FIGS. 11A, 11B, and 12 includes the piezoelectric layer 100, the first IDT electrode 11, the plurality of first reflectors 31, the second IDT electrode 22, the plurality of second reflectors 42, the first insulating layer 113, the low-acoustic-velocity layer 153 (second insulating layer 114), and the high-acoustic-velocity support substrate 155. In this example, the first region m1 and the inter-reflector region MR are the same or substantially the same region in the first direction d1.

As illustrated in FIG. 12, in one end region E of the inter-reflector region MR in the first direction d1, the second reflective electrode finger 42a is disposed on the second main surface 100b, but no reflective electrode finger is disposed on the first main surface 100a. In this example, in a region, on the first main surface 100a, that is located in the third direction d3 as viewed from the second reflective electrode finger 42a located in one end region E, no first reflective electrode finger is disposed and the first insulating layer 113 is provided.

In addition, as illustrated in FIG. 12, in the other end region E of the inter-reflector region MR in the first direction d1, the second reflective electrode finger 42a is disposed on the second main surface 100b, but no reflective electrode finger is disposed on the first main surface 100a. In this example, in a region, on the first main surface 100a, that is located in the third direction d3 as viewed from the second reflective electrode finger 42a located in the other end region E, no first reflective electrode finger is disposed and the first insulating layer 113 is provided.

That is, in both of one end region E and the other end region E of the inter-reflector region MR in the first direction d1, the acoustic wave element 10C includes the regions in which none of the first reflective electrode fingers 31a and the second reflective electrode fingers 42a face each other in the third direction d3.

The second reflective electrode finger that does not face the first reflective electrode finger in each of the end regions E includes at least the second reflective electrode finger closest to the second IDT electrode 22 of the plurality of second reflective electrode fingers 42a arranged in the first direction d1. One second reflective electrode finger 42a that does not face the first reflective electrode finger in each of the end regions E is illustrated in this drawing, but the number of second reflective electrode fingers that do not face the first reflective electrode fingers is not limited to one and may be, for example, two or more.

For example, the number of first reflective electrode fingers 31a and second reflective electrode fingers 42a that do not face each other in each of the end regions E is preferably more than about 0% and not more than about 2.5% of the total number of second electrode fingers 22a and 22b and second reflective electrode fingers 42a. That is, for example, the number of first reflective electrode fingers 31a and second reflective electrode fingers 42a that do not face each other in both one end region E and the other end region E is preferably more than about 0% and not more than about 5% of the total number of second electrode fingers 22a and 22b and second reflective electrode fingers 42a.

For example, when the total number of second electrode fingers 22a and 22b and second reflective electrode fingers 42a is 222, the number of first reflective electrode fingers 31a and second reflective electrode fingers 42a that do not face each other in each of the end regions E may be, for example, 1, 2 or 5. The number of first reflective electrode fingers 31a and second reflective electrode fingers 42a that do not face each other in both one end region E and the other end region E may be, for example, 2, 4, or 10.

Since there are regions in which none of the first reflective electrode fingers 31a and the second reflective electrode fingers 42a face each other in the third direction d3 in the end regions E of the inter-reflector region MR in the first direction d1 as described above, ripples can be reduced or prevented from occurring at frequencies higher than the anti-resonance frequency of the acoustic wave element 10C.

### Fourth Modification of First Example Embodiment

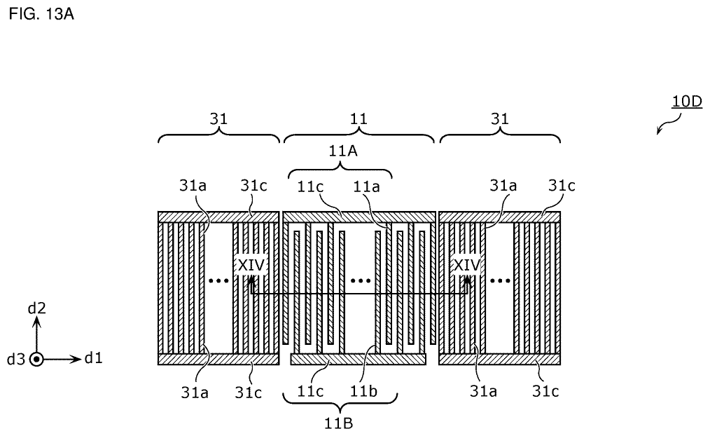

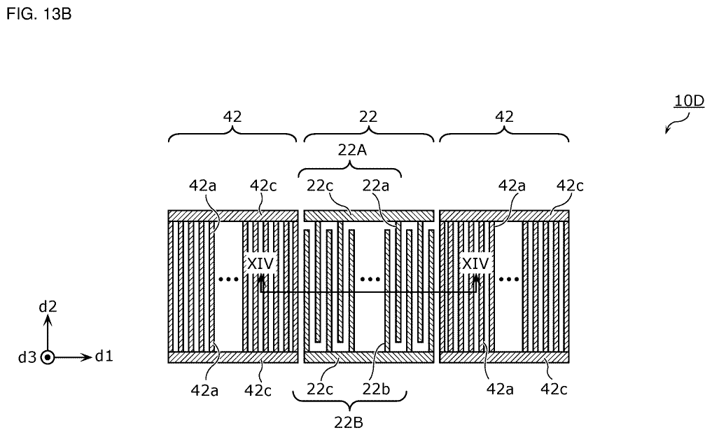

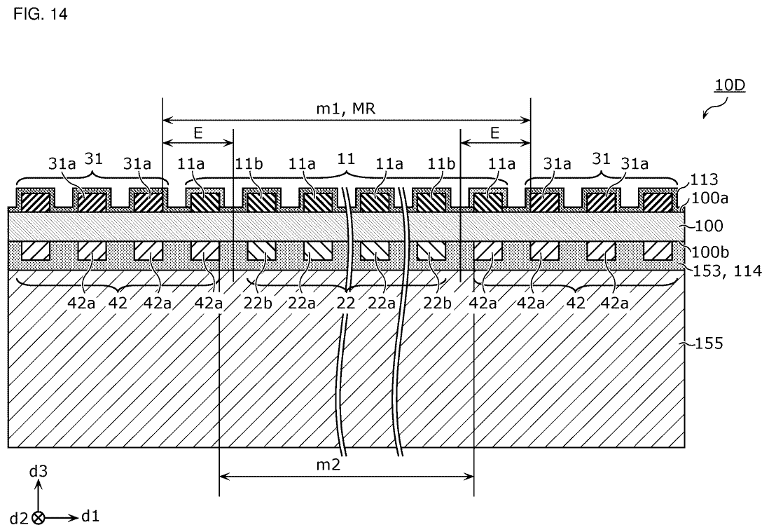

An acoustic wave element 10D according to a fourth modification of the first example embodiment will be described with reference to FIGS. 13A to 14. In the fourth modification, an example in which the first electrode fingers in the end portions of the first IDT electrode 11 do not face the second electrode fingers in the end portions of the second IDT electrode 22 but face the second reflective electrode fingers in the end portions of the second reflectors will be described.

FIG. 13A is a top view of the first IDT electrode 11 and the first reflectors 31 of the acoustic wave element 10D according to the fourth modification of the first example embodiment. FIG. 13B is a top view of a second IDT electrode 22 and second reflectors 42 of the acoustic wave element 10D. FIG. 14 is a cross-sectional view of the acoustic wave element 10D illustrated in FIGS. 13A and 13B taken along line XIV-XIV.

The acoustic wave element 10D illustrated in FIGS. 13A, 13B, and 14 includes the piezoelectric layer 100, the first IDT electrode 11, the plurality of first reflectors 31, the second IDT electrode 22, the plurality of second reflectors 42, the first insulating layer 113, the low-acoustic-velocity layer 153 (second insulating layer 114), and the high-acoustic-velocity support substrate 155. In this example, the first region m1 and the inter-reflector region MR are the same or substantially the same region in the first direction d1.

As illustrated in FIG. 14, in one end region E of the inter-reflector region MR in the first direction d1, the first electrode finger 11a is disposed on the first main surface 100a, but no second electrode finger is disposed on the second main surface 100b. In this example, in a region, on the second main surface 100b, that is located in the third direction d3 as viewed from the first electrode finger 11a located in one end region E, no second electrode finger is disposed and the second reflective electrode finger 42a is disposed.

In addition, as illustrated in FIG. 14, in the other end region E of the inter-reflector region MR in the first direction d1, the first reflective electrode finger 11a is disposed on the first main surface 100a, but no second electrode finger is disposed on the second main surface 100b. In this example, in a region, on the second main surface 100b, that is located in the third direction d3 as viewed from the first electrode finger 11a located in the other end region E, no second electrode finger is disposed and the second reflective electrode finger 42a is disposed.

That is, in both of one end region E and the other end region E of the inter-reflector region MR in the first direction d1, the acoustic wave element 10D includes the region in which none of the first electrode fingers 11a and 11b and the second electrode fingers 22a and 22b face each other in the third direction d3 and the region in which none of the first reflective electrode fingers 31a and the second reflective electrode fingers 42a face each other in the third direction d3.

For example, the number of first electrode fingers 11a and 11b and second electrode fingers 22a and 22b that do not face each other in each of the end regions E is preferably more than about 0% and not more than about 2.5% of the total number of first electrode fingers 11a and 11b and first reflective electrode fingers 31a. That is, for example, the number of first electrode fingers 11a and 11b and second electrode fingers 22a and 22b that do not face each other in both one end region E and the other end region E is preferably more than about 0% and not more than about 5% of the total number of first electrode fingers 11a and 11b and first reflective electrode fingers 31a.

For example, the number of first reflective electrode fingers 31a and second reflective electrode fingers 42a that do not face each other in each of the end regions E is preferably more than about 0% and not more than about 2.5% of the total number of second electrode fingers 22a and 22b and second reflective electrode fingers 42a. That is, for example, the number of first reflective electrode fingers 31a and second reflective electrode fingers 42a that do not face each other in both one end region E and the other end region E is preferably more than about 0% and not more than about 5% of the total number of second electrode fingers 22a and 22b and second reflective electrode fingers 42a.

For example, when the total number of first electrode fingers 11a and 11b and the first reflective electrode fingers 31a is 222, the number of first electrode fingers 11a and 11b and second electrode fingers 22a and 22b that do not face each other in each of the end regions E may be 1, 2, or 5. The number of first electrode fingers 11a and 11b and second electrode fingers 22a and 22b that do not face each other in both one end region E and the other end region E may be, for example, 2, 4, or 10.

For example, when the total number of second electrode fingers 22a and 22b and second reflective electrode fingers 42a is 222, the number of first reflective electrode fingers 31a and second reflective electrode fingers 42a that do not face each other in each of the end regions E may be 1, 2, or 5. The number of first reflective electrode fingers 31a and second reflective electrode fingers 42a that do not face each other in both one end region E and the other end region E may be, for example, 2, 4, or 10.

Since there are the region in which none of the first electrode fingers 11a and 11b and the second electrode fingers 22a and 22b face each other in the third direction d3 and the region in which none of the first reflective electrode fingers 31a and the second reflective electrode fingers 42a face each other in the third direction d3 in the end regions E of the inter-reflector region MR in the first direction d1 as described above, ripples can be reduced or prevented from occurring at frequencies higher than the anti-resonance frequency of the acoustic wave element 10D.

### Fifth Modification of First Example Embodiment

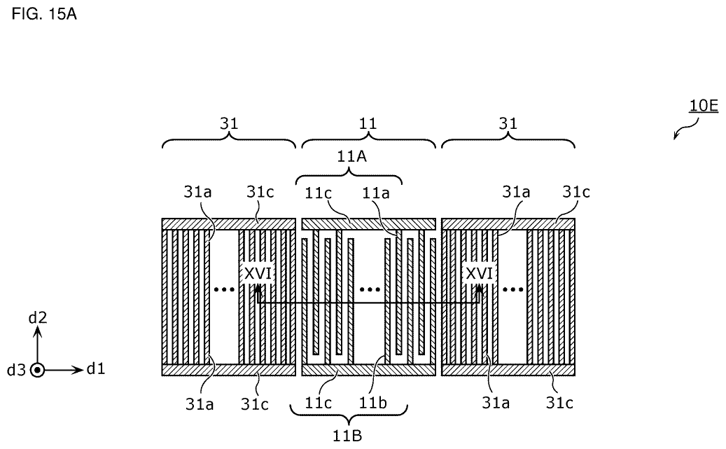

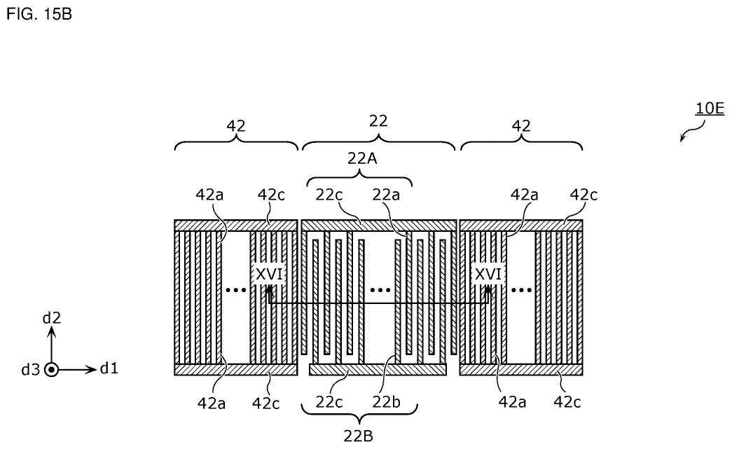

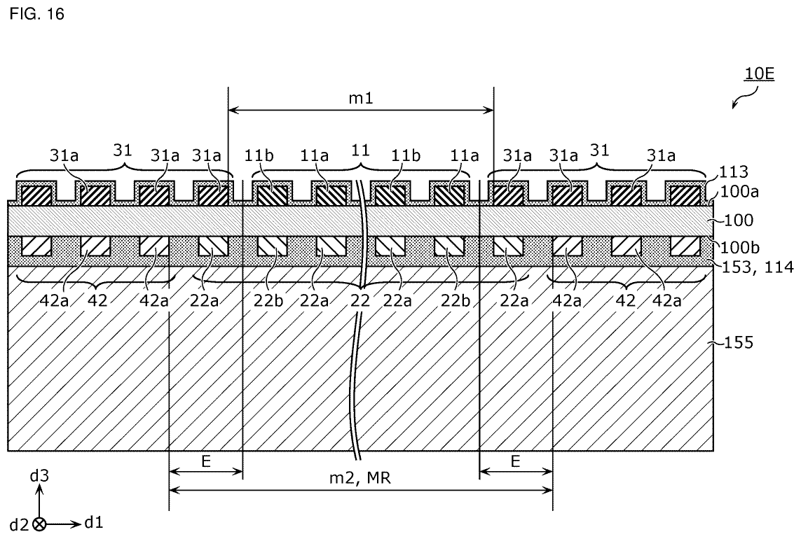

An acoustic wave element 10E according to a fifth modification of the first example embodiment will be described with reference to FIGS. 15A to 16. In the fifth modification, an example in which the second electrode fingers in the end portions of the second IDT electrode 22 do not face the first electrode fingers in the end portions of the first IDT electrode 11 but face the first reflective electrode fingers in the end portions of the first reflectors will be described.

FIG. 15A is a top view of the first IDT electrode 11 and the first reflectors 31 of the acoustic wave element 10E according to the fifth modification of the first example embodiment. FIG. 15B is a top view of a second IDT electrode 22 and second reflectors 42 of the acoustic wave element 10E. FIG. 16 is a cross-sectional view of the acoustic wave element 10E illustrated in FIGS. 15A and 15B taken along line XVI-XVI.

An acoustic wave element 10E illustrated in FIGS. 15A, 15B, and 16 includes the piezoelectric layer 100, the first IDT electrode 11, the plurality of first reflectors 31, the second IDT electrode 22, the plurality of second reflectors 42, the first insulating layer 113, the low-acoustic-velocity layer 153 (second insulating layer 114), and the high-acoustic-velocity support substrate 155. In this example, the second region m2 and the inter-reflector region MR are the same or substantially the same region in the first direction d1.

As illustrated in FIG. 16, in one end region E of the inter-reflector region MR in the first direction d1, the second electrode finger 22a is disposed on the second main surface 100b, but no first electrode finger is disposed on the first main surface 100a. In this example, in a region, on the first main surface 100a, that is located in the third direction d3 as viewed from the second electrode finger 22a located in one end region E, no first electrode finger is disposed and the first reflective electrode finger 31a is disposed.

In addition, as illustrated in FIG. 16, in the other end region E of the inter-reflector region MR in the first direction d1, the second reflective electrode finger 22a is disposed on the second main surface 100b, but no first electrode finger is disposed on the first main surface 100a. In this example, in a region, on the first main surface 100a, that is located in the third direction d3 as viewed from the second electrode finger 22a located in the other end region E, no first electrode finger is disposed and the first reflective electrode finger 31a is disposed.

That is, in both of one end region E and the other end region E of the inter-reflector region MR in the first direction d1, the acoustic wave element 10E includes the region in which none of the first electrode fingers 11a and 11b and the second electrode fingers 22a and 22b face each other in the third direction d3 and the region in which none of the first reflective electrode fingers 31a and the second reflective electrode fingers 42a face each other in the third direction d3.

For example, the number of first electrode fingers 11a and 11b and second electrode fingers 22a and 22b that do not face each other in each of the end regions E is preferably more than about 0% and not more than about 2.5% of the total number of second electrode fingers 22a and 22b and second reflective electrode fingers 42a. That is, for example, the number of first electrode fingers 11a and 11b and second electrode fingers 22a and 22b that do not face each other in both one end region E and the other end region E is preferably more than about 0% and not more than about 5% of the total number of second electrode fingers 22a and 22b and second reflective electrode fingers 42a.

For example, the number of first reflective electrode fingers 31a and second reflective electrode fingers 42a that do not face each other in each of the end regions E is preferably more than about 0% and not more than about 2.5% of the total number of first electrode fingers 11a and 11b and first reflective electrode fingers 31a. That is, for example, the number of first reflective electrode fingers 31a and second reflective electrode fingers 42a that do not face each other in both one end region E and the other end region E is preferably more than about 0% and not more than about 5% of the total number of first electrode fingers 11a and 11b and first reflective electrode fingers 31a.

For example, when the total number of second electrode fingers 22a and 22b and second reflective electrode fingers 42a is 222, the number of first electrode fingers 11a and 11b and second electrode fingers 22a and 22b that do not face each other in each of the end regions E may be 1, 2 or 5. The number of first electrode fingers 11a and 11b and second electrode fingers 22a and 22b that do not face each other in both one end region E and the other end region E may be, for example, 2, 4, or 10.

For example, when the total number of first electrode fingers 11a and 11b and first reflective electrode fingers 31a is 222, the number of first reflective electrode fingers 31a and second reflective electrode fingers 42a that do not face each other in each of the end regions E may be 1, 2, or 5. The number of first reflective electrode fingers 31a and second reflective electrode fingers 42a that do not face each other in both one end region E and the other end region E may be, for example, 2, 4, or 10.

Since there are the region in which none of the first electrode fingers 11a and 11b and the second electrode fingers 22a and 22b face each other in the third direction d3 and the region in which none of the first reflective electrode fingers 31a and the second reflective electrode fingers 42a face each other in the third direction d3 in the end regions E of the inter-reflector region MR in the first direction d1 as described above, ripples can be reduced or prevented from occurring at frequencies higher than the anti-resonance frequency of the acoustic wave element 10E.

### Second Example Embodiment

In a second example embodiment of the present invention, a ladder acoustic wave filter device including the acoustic wave element 10 according to the first example embodiment will be described.

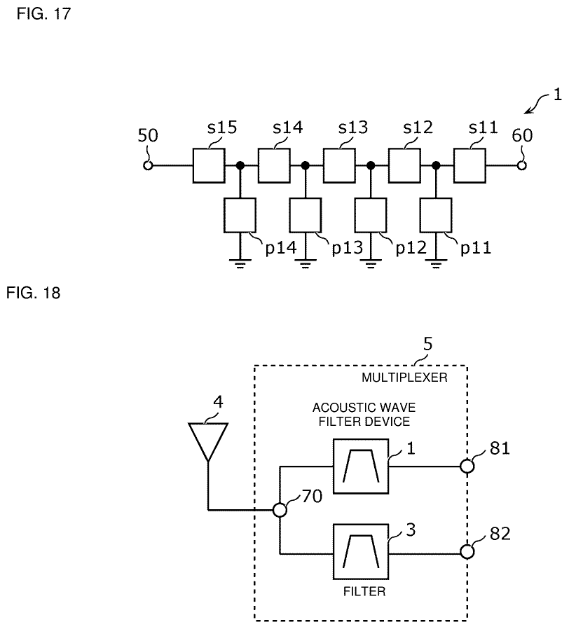

FIG. 17 is a diagram illustrating a circuit structure of an acoustic wave filter device 1 according to the second example embodiment. As illustrated in FIG. 17, the acoustic wave filter device 1 includes series arm resonators s11, s12, s13, s14, and s15, parallel arm resonators p11, p12, p13, and p14, and terminals 50 and 60.

The series arm resonators s11 to s15 are connected in series between the terminal 50 and the terminal 60. In addition, the parallel arm resonators p11 to p14 are connected in parallel between the reference terminals (ground) and the connection points of the terminal 50, the series arm resonators s11 to s15, and the terminal 60. The acoustic wave filter device 1 defines a ladder bandpass filter due to the connection structure described above of the series arm resonators s11 to s15 and the parallel arm resonators p11 to p14. Circuit elements, such as inductors, for example, may be inserted between the parallel arm resonators p11 to p14 and the ground.

In the second example embodiment, all of the series arm resonators s11 to s15 and the parallel arm resonators p11 to p14 included in the acoustic wave filter device 1 may be defined by the acoustic wave elements 10 described above. Alternatively, only the parallel arm resonators p11 to p14 of the resonators included in the acoustic wave filter device 1 may be defined by the acoustic wave elements 10 described above. Alternatively, either the parallel arm resonator p14 or the series arm resonator s15 closest to the terminal 50 connected to the common terminal of the resonators included in the acoustic wave filter device 1 may be defined by the acoustic wave element 10 described above.

The acoustic wave filter device 1 need only have a structure including the acoustic wave element according to the first example embodiment. The circuit structure illustrated in FIG. 17 is an example thereof, and the number of series arm resonators, the number of parallel arm resonators, the connection points of inductors, and the like are not limited to the structure illustrated in FIG. 17. In addition, for example, a ladder circuit structure has been illustrated in FIG. 17, but a vertically-coupled resonant circuit may be included.

### Third Example Embodiment

In a third example embodiment of the present invention, a multiplexer having a structure in which a plurality of filters including the acoustic wave filter device 1 according to the second example embodiment are directly or indirectly connected to the common terminal will be described.

FIG. 18 is a circuit structure diagram of a multiplexer 5 according to the third example embodiment and its peripheral circuit (antenna 4). The multiplexer 5 illustrated in FIG. 18 includes the acoustic wave filter device 1, a filter 3, a common terminal 70, and input/output terminals 81 and 82.

In the acoustic wave filter device 1, a terminal 50 of the acoustic wave filter device 1 is connected to the common terminal 70, and the terminal 60 of the acoustic wave filter device 1 is connected to the input/output terminal 81.

The filter 3 is connected to the common terminal 70 and the input/output terminal 82. The filter 3 is, for example, a ladder acoustic wave filter including parallel arm resonators and series arm resonators but may also be an LC filter, and the circuit structure thereof is not particularly limited.

Here, for example, the passband of the acoustic wave filter device 1 is lower than the passband of the filter 3.

The acoustic wave filter device 1 and the filter 3 need not be directly connected to the common terminal 70 unlike FIG. 18 and may be indirectly connected to the common terminal 70 through, for example, an impedance matching circuit, a phase shifter, a circulator, or a switch element capable of selecting two or more filters.

The multiplexer 5 has a circuit structure in which two filters are connected to the common terminal 70 in the present example embodiment, but the number of filters connected to the common terminal 70 is not limited to two and may be three or more.

That is, a multiplexer according to an example embodiment of the present invention may include a plurality of filters including the acoustic wave filter device 1, one of input/output terminals of the plurality of filters may be directly or indirectly connected to the common terminal, and at least one of the plurality of filters excluding the acoustic wave filter device 1 may have a passband higher than frequencies in the passband of the acoustic wave filter device 1.

### SUMMARY

The structures of the acoustic wave elements 10, 10A, 10B, 10C, 10D, and 10E, the acoustic wave filter device 1, and the multiplexer 5 according to example embodiments of the present invention will be described below.

An acoustic wave element according to a first example includes the first IDT electrode 11 and the plurality of first reflectors 31 that are provided on the first main surface 100a of the piezoelectric layer 100 and the second IDT electrode 22 and the plurality of second reflectors 42 that are provided on the second main surface 100b of the piezoelectric layer 100 and faces away from the first main surface 100a. The first IDT electrode 11 includes the plurality of first electrode fingers 11a and 11b extending in the second direction d2 crossing the first direction d1 in the direction along the first main surface 100a. The plurality of first reflectors 31 are disposed on both outer sides of the first IDT electrode 11 in the first direction d1 and each include the plurality of first reflective electrode fingers 31a extending in the second direction d2. The second IDT electrode 22 includes the plurality of second electrode fingers 22a and 22b extending in the second direction d2 crossing the first direction d1 in the direction along the second main surface 100b. The plurality of second reflectors 42 are disposed on both outer sides of the second IDT electrode 22 in the first direction d1 and each include the plurality of second reflective electrode fingers 42a extending in the second direction d2. When the region between the plurality of first reflectors 31 in the first direction d1 is the first region m1, the region between the plurality of second reflectors 42 in the first direction d1 is the second region m2, and the minimum region including the first region m1 and the second region m2 as viewed in the third direction d3 orthogonal or substantially orthogonal to the first direction d1 and the second direction d2 is the inter-reflector region MR, (1) there is a region in which none of the first electrode fingers 11a and 11b and the second electrode fingers 22a and 22b face each other in the third direction d3 in the end region E of the inter-reflector region MR in the first direction d1, or (2) there is a region in which none of the first reflective electrode fingers 31a and the second reflective electrode fingers 42a face each other in the third direction d3 in the end region E of the inter-reflector region MR in the first direction d1.

Since there is the region in which none of the first electrode fingers 11a and 11b and the second electrode fingers 22a and 22b face each other in the third direction d3 in the end region E of the inter-reflector region MR in the first direction d1 as described in (1), ripples can be reduced or prevented from occurring at frequencies higher than the anti-resonance frequency of the acoustic wave element. Alternatively, since there is the region in which none of the first reflective electrode fingers 31a and the second reflective electrode fingers 42a face each other in the third direction d3 in the end region E of the inter-reflector region MR in the first direction d1 as described in (2), ripples can be reduced or prevented from occurring at frequencies higher than the anti-resonance frequency of the acoustic wave element.

An acoustic wave element 10 according to a second example is the acoustic wave element according to the first example, further including the second insulating layer 114 provided on the second main surface 100b to cover the plurality of second electrode fingers 22a and 22b and the plurality of second reflective electrode fingers 42a. In a region, on the second main surface 100b, that is located in the third direction d3 as viewed from one or more of the first electrode fingers (for example, the first electrode finger 11a) located in the end region E, none of the second electrode fingers may be disposed and the second insulating layer 114 may be provided.

As described above, the region in which none of the first electrode fingers and the second electrode fingers face each other in the third direction d3 can be defined by the second insulating layer 114 being provided in the region located in the third direction d3 as viewed from one or more of the first electrode fingers located in the end region E. As a result, ripples can be reduced or prevented from occurring at frequencies higher than the anti-resonance frequency of the acoustic wave element 10.

An acoustic wave element 10A according to a third example is the acoustic wave element according to the first example, further including the first insulating layer 113 provided on the first main surface 100a to cover the plurality of first electrode fingers 11a and 11b and the plurality of first reflective electrode fingers 31a. In a region, on the first main surface 100a, that is located in the third direction d3 as viewed from one or more of the second electrode fingers (for example, second electrode finger 22a) located in the end region E, none of the first electrode fingers may be disposed and the first insulating layer 113 may be provided.

As described above, the region in which none of the first electrode fingers and the second electrode fingers face each other in the third direction d3 can be defined by the first insulating layer 113 being provided in the region located in the third direction d3 as viewed from one or more of the second electrode fingers located in the end region E. As a result, ripples can be reduced or prevented from occurring at frequencies higher than the anti-resonance frequency of the acoustic wave element 10A.

An acoustic wave element 10B according to a fourth example is the acoustic wave element according to the first example, further including the second insulating layer 114 provided on the second main surface 100b to cover the plurality of second electrode fingers 22a and 22b and the plurality of second reflective electrode fingers 42a. In a region, on the second main surface 100b, that is located in the third direction d3 as viewed from one or more of the first reflective electrode fingers (for example, the first reflective electrode finger 31a) located in the end region E, none of the second electrode fingers may be disposed and the second insulating layers 114 may be provided.

As described above, the region in which none of the first reflective electrode fingers and the second reflective electrode fingers face each other in the third direction d3 can be defined by the second insulating layer 114 being provided in the region located in the third direction d3 as viewed from one or more of the first reflective electrode fingers located in the end region E. As a result, ripples can be reduced or prevented from occurring at frequencies higher than the anti-resonance frequency of the acoustic wave element 10B.

An acoustic wave element 10C according to a fifth example is the acoustic wave element according to the first example, further including the first insulating layer 113 provided on the first main surface 100a to cover the plurality of first electrode fingers 11a and 11b and the plurality of first reflective electrode fingers 31a. In a region, on the first main surface 100a, that is located in the third direction d3 as viewed from one or more of the second reflective electrode fingers (for example, the second reflective electrode finger 42a) located in the end region E, none of the first reflective electrode fingers 31a may be disposed and the first insulating layer 113 may be provided.

As described above, the region in which none of the first reflective electrode fingers and the second reflective electrode fingers face each other in the third direction d3 can be defined by the first insulating layer 113 being provided in the region located in the third direction d3 as viewed from one or more of the second reflective electrode fingers located in the end region E. As a result, ripples can be reduced or prevented from occurring at frequencies higher than the anti-resonance frequency of the acoustic wave element 10C.

An acoustic wave element according to a sixth example is the acoustic wave element according to the first example, in which, in the end region E of the inter-reflector region MR in the first direction d1, there may be the region in which none of the first electrode fingers 11a and 11b and the second electrode fingers 22a and 22b face each other in the third direction d3 and the region in which none of the first reflective electrode fingers 31a and the second reflective electrode fingers 42a face each other in the third direction d3.

Since there is the region in which none of the first electrode fingers 11a and 11b and the second electrode fingers 22a and 22b face each other in the third direction d3 and the region in which none of the first reflective electrode fingers 31a and the second reflective electrode fingers 42a face each other in the third direction d3 as described above, ripples can be reduced or prevented from occurring at frequencies higher than the anti-resonance frequency of the acoustic wave element.

An acoustic wave element 10D according to a seventh example is the acoustic wave element according to the sixth example, in which, in a region, on the second main surface 100b, that is located in the third direction d3 as viewed from one or more of the first electrode fingers (for example, the first electrode finger 11a) located in the end region E, none of the second electrode fingers may be disposed and the second reflective electrode finger 42a may be disposed.

As described above, by the second reflective electrode finger 42a being provided in the region located in the third direction d3 as viewed from one or more of the first electrode fingers located in the end region E, the region in which none of the first electrode fingers and the second electrode fingers face each other in the third direction d3 can be provided, and the region in which none of the first reflective electrode fingers and the second reflective electrode fingers face each other in the third direction d3 can be provided. As a result, ripples can be reduced or prevented from occurring at frequencies higher than the anti-resonance frequency of the acoustic wave element 10D.

An acoustic wave element 10E according to an eighth example is the acoustic wave element according to the sixth example, in which, in a region, on the first main surface 100a, that is located in the third direction d3 as viewed from one or more of the second electrode fingers (for example, the second electrode finger 22a) located in the end region E, none of the first electrode fingers may be disposed and the first reflective electrode finger 31a may be disposed.

As described above, by the first reflective electrode finger 31a being disposed in the region located in the third direction d3 as viewed from one or more of the second electrode fingers located in the end region E, the region in which none of the first electrode fingers and the second electrode fingers face each other in the third direction d3 can be provided, and the region in which none of the first reflective electrode fingers and the second reflective electrode fingers face each other in the third direction d3 can be provided. As a result, ripples can be reduced or prevented from occurring at frequencies higher than the anti-resonance frequency of the acoustic wave element 10E.

An acoustic wave element according to a ninth example is the acoustic wave element according to any one of the first to eighth examples, in which the end region E include one end region E and another end region E of the inter-reflector region MR in the first direction d1. In one end region E and the other end region E, the number of first electrode fingers 11a and 11b and second electrode fingers 22a and 22b that do not face each other may be more than about 0% and not more than about 5% of the total number of first electrode fingers 11a and 11b and first reflective electrode fingers 31a or the total number of second electrode fingers 22a and 22b and second reflective electrode fingers 42a.

When the number of first electrode fingers 11a and 11b and second electrode fingers 22a and 22b that do not face each other falls within the range described above, ripples can be reduced or prevented from occurring at frequencies higher than the anti-resonance frequency of the acoustic wave element. In addition, when the number of first electrode fingers that do not face each other is not more than about 5%, the phase value that represents the inductiveness of the impedance of the acoustic wave element can be reduced or prevented from becoming unnecessarily small. In addition, when the number of first electrode fingers that do not face each other is not more than about 5%, the inductive impedance of the acoustic wave element can be reduced or prevented from changing to the capacitive impedance.

An acoustic wave element 10A according to a tenth example is the acoustic wave element according to any one of the first to eighth examples, in which the end region E includes one end region E and another end region E of the inter-reflector region MR in the first direction d1. In the one end region E and the other end region E, the number of first reflective electrode fingers 31a and second reflective electrode fingers 42a that do not face each other may be more than about 0% and not more than about 5% of the total number of first electrode fingers 11a and 11b and first reflective electrode fingers 31a or the total number of second electrode fingers 22a and 22b and second reflective electrode fingers 42a. When the number of first reflective electrode fingers 31a and second reflective electrode fingers 42a that do not face each other falls within the range described above, ripples can be reduced or prevented from occurring at frequencies higher than the anti-resonance frequency of the acoustic wave element. In addition, when the number of reflective electrode fingers that do not face each other is not more than about 5%, the phase value representing the inductiveness of the impedance of the acoustic wave element can be reduced or prevented from becoming unnecessarily small. In addition, when the number of reflective electrode fingers that do not face each other is not more than about 5%, the inductive impedance of the acoustic wave element can be reduced or prevented from changing to the capacitive impedance.

An acoustic wave element according to an eleventh example is the acoustic wave element according to any one of the first to tenth examples, further including the high-acoustic-velocity support substrate 155 through which bulk waves propagate at an acoustic velocity higher than an acoustic velocity of acoustic waves propagating through the piezoelectric layer 100, and the low-acoustic-velocity layer 153 that is disposed between the high-acoustic-velocity support substrate 155 and the piezoelectric layer 100 and through which bulk waves propagate at an acoustic velocity lower than the acoustic velocity of the acoustic waves propagating through the piezoelectric layer 100. The low-acoustic-velocity layer 153 may be provided on the second main surface 100b so as to cover the second IDT electrode 22. The piezoelectric layer 100 is supported by the low-acoustic-velocity layer 153 even in a portion in which acoustic waves are excited because the second IDT electrode 22 is embedded in the low-acoustic-velocity layer 153 as described above, and accordingly, the shape of the piezoelectric layer 100 is not easily deformed, and electrical characteristics can be reduced or prevented from fluctuating. In addition, since the second IDT electrode 22 is embedded in the low-acoustic-velocity layer 153, higher-order modes can leak toward the low-acoustic-velocity layer 153. As a result, generation of higher-order modes can be reduced or prevented.

An acoustic wave filter device according to a twelfth example includes an acoustic wave element 10 according to any one of the first to eleventh examples.

As a result, the acoustic wave filter device 1 including an acoustic wave element that can reduce or prevent ripples from occurring at frequencies higher than the anti-resonance frequency can be provided.

A multiplexer 5 according to a thirteenth example embodiment includes the plurality of filters 3 including the acoustic wave filter device 1 according to the twelfth example. One of the input/output terminal 81 and the input/output terminal 82 of each of the plurality of filters 3 is directly or indirectly connected to the common terminal 70, and at least one of the plurality of filters 3 excluding the acoustic wave filter device 1 has a passband higher than frequencies in the passband of the acoustic wave filter device 1.

Since this can increase the attenuation amount in the attenuation band higher than the passband, the insertion loss in the passband of the filter having a passband higher than the passband of the acoustic wave filter device 1 can be reduced.

### OTHER EXAMPLE EMBODIMENTS ETC

The acoustic wave elements, the acoustic wave filter devices, and the multiplexers according to example embodiments of the present invention have been described above by using example embodiments and examples, but it should be noted that the acoustic wave elements, the acoustic wave filter devices, and the multiplexers according to the present invention are not limited to the example embodiments and the examples described above. Other example embodiments achieved by combining any components in the example embodiments and the examples, examples obtained by those skilled in the art applying various modifications to the example embodiments without departing from the concept of the present invention, and various devices incorporating the acoustic wave elements, the acoustic wave filter devices, and the multiplexers according to the present invention are also included in the present invention.

For example, the acoustic wave filter device 1 according to an example embodiment of the present invention may further include circuit elements, such as inductors and capacitors, for example.

In addition, the acoustic wave element according to the present invention need not be a surface acoustic wave resonator according to the first example embodiment and may be, for example, an acoustic wave resonator that uses acoustic boundary waves.

In addition, an example in which the low-acoustic-velocity layer 153 and the high-acoustic-velocity support substrate 155 are provided on the second main surface 100b of the piezoelectric layer 100 has been described above, but the present invention is not limited to this example, and, for example, only the support substrate may be provided on the second main surface 100b of the piezoelectric layer 100.

In addition, the acoustic wave element 10 illustrated in FIGS. 1A, 1B, 2, and 3 is intended to describe a typical structure, and the number and the length of electrode fingers that define the electrode are not limited to this example. The materials of individual layers used for the laminated structure of the piezoelectric layer 100 and the like are only examples and can be changed depending on important characteristics of the required high-frequency propagation characteristics.

In the description of the example embodiments described above, the arrangement pitch of electrode fingers refers to the middle-to-middle distance in the first direction d1 between first electrode fingers 11a and 11b adjacent to each other in the first direction d1 of the plurality of first electrode fingers 11a and 11b included in, for example, the first IDT electrode 11. The same applies to the second IDT electrode 22. The arrangement pitch of reflective electrode fingers refers to the middle-to-middle distance in the first direction d1 between first reflective electrode fingers 31a adjacent to each other in the first direction d1 of the plurality of first reflective electrode fingers 31a included in, for example, the first reflector 31. The same applies to the second reflector 42.

Example embodiments of the present invention are widely used for communication devices, such as, for example, mobile phones, low-loss and small-sized acoustic wave elements, acoustic wave filters, and multiplexers that are applicable to multi-band and multi-mode frequency standards.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave element comprising:
a piezoelectric layer;
a first IDT electrode and a plurality of first reflectors on a first main surface of the piezoelectric layer; and
a second IDT electrode and a plurality of second reflectors on a second main surface of the piezoelectric layer, the second main surface facing away from the first main surface; wherein
the first IDT electrode includes a plurality of first electrode fingers extending in a second direction crossing a first direction in a direction along the first main surface;
the plurality of first reflectors are located on both outer sides of the first IDT electrode in the first direction, each of the plurality of first reflectors including a plurality of first reflective electrode fingers extending in the second direction;
the second IDT electrode includes a plurality of second electrode fingers extending in the second direction crossing the first direction in a direction along the second main surface;
the plurality of second reflectors are located on both outer sides of the second IDT electrode in the first direction, each of the plurality of second reflectors including a plurality of second reflective electrode fingers extending in the second direction; and
when a region between the plurality of first reflectors in the first direction is a first region, a region between the plurality of second reflectors in the first direction is a second region, and a minimum region including the first region and the second region as viewed in a third direction orthogonal to the first direction and the second direction is an inter-reflector region, in an end region of the inter-reflector region in the first direction, a region is provided in which none of the first electrode fingers and the second electrode fingers face each other in the third direction, or, in the end region of the inter-reflector region in the first direction, a region is provided in which none of the first reflective electrode fingers and the second reflective electrode fingers face each other in the third direction.

2. The acoustic wave element according to claim 1, further comprising:
a second insulating layer on the second main surface and covering the plurality of second electrode fingers and the plurality of second reflective electrode fingers; wherein
in a region, on the second main surface, located in the third direction as viewed from one or more of the first electrode fingers located in the end region, none of the second electrode fingers are provided and the second insulating layer is provided.

3. The acoustic wave element according to claim 1, further comprising:
a first insulating layer on the first main surface and covering the plurality of first electrode fingers and the plurality of first reflective electrode fingers; wherein
in a region, on the first main surface, located in the third direction as viewed from one or more of the second electrode fingers located in the end region, none of the first electrode fingers are provided and the first insulating layer is provided.

4. The acoustic wave element according to claim 1, further comprising:
a second insulating layer on the second main surface and covering the plurality of second electrode fingers and the plurality of second reflective electrode fingers; wherein
in a region, on the second main surface, located in the third direction as viewed from one or more of the first reflective electrode fingers located in the end region, none of the second reflective electrode fingers are provided and the second insulating layer is provided.

5. The acoustic wave element according to claim 1, further comprising:
a first insulating layer on the first main surface and covering the plurality of first electrode fingers and the plurality of first reflective electrode fingers; wherein
in a region, on the first main surface, located in the third direction as viewed from one or more of the second reflective electrode fingers located in the end region, none of the first reflective electrode fingers are provided and the first insulating layer is provided.

6. The acoustic wave element according to claim 1, wherein, in the end region of the inter-reflector region in the first direction, the region in which none of the first electrode fingers and the second electrode fingers face each other in the third direction, and the region in which none of the first reflective electrode fingers and the second reflective electrode fingers face each other in the third direction are provided.

7. The acoustic wave element according to claim 6, wherein, in a region, on the second main surface, located in the third direction as viewed from one or more of the first electrode fingers located in the end region, none of the second electrode fingers are provided and one or more of the second reflective electrode fingers are provided.

8. The acoustic wave element according to claim 6, wherein, in a region, on the first main surface, located in the third direction as viewed from one or more of the second electrode fingers located in the end region, none of the first electrode fingers are provided and one or more of the first reflective electrode fingers are provided.

9. The acoustic wave element according to claim 1, wherein
the end region includes one end region and another end region of the inter-reflector region in the first direction; and
in the one end region and the other end region, a number of first electrode fingers and second electrode fingers that do not face each other is more than about 0% and not more than about 5% of the total number of first electrode fingers and first reflective electrode fingers or the total number of second electrode fingers and second reflective electrode fingers.

10. The acoustic wave element according to claim 1, wherein
the end region includes one end region and another end region of the inter-reflector region in the first direction; and
in the one end region and the other end region, a number of first reflective electrode fingers and second reflective electrode fingers that do not face each other is more than about 0% and not more than about 5% of the total number of first electrode fingers and first reflective electrode fingers or the total number of second electrode fingers and second reflective electrode fingers.

11. The acoustic wave element according to claim 1, further comprising:
a high-acoustic-velocity support substrate through which a bulk wave propagates at an acoustic velocity higher than an acoustic velocity of an acoustic wave propagating through the piezoelectric layer; and
a low-acoustic-velocity layer through which a bulk wave propagates at an acoustic velocity lower than the acoustic velocity of the acoustic wave propagating through the piezoelectric layer, the low-acoustic-velocity layer being between the high-acoustic-velocity support substrate and the piezoelectric layer; wherein
the low-acoustic-velocity layer is provided on the second main surface and covers the second IDT electrode and the second reflectors.

12. An acoustic wave filter device comprising:
the acoustic wave element according to claim 1.

13. The acoustic wave filter device according to claim 12, further comprising:
a second insulating layer on the second main surface and covering the plurality of second electrode fingers and the plurality of second reflective electrode fingers; wherein
in a region, on the second main surface, located in the third direction as viewed from one or more of the first electrode fingers located in the end region, none of the second electrode fingers are provided and the second insulating layer is provided.

14. The acoustic wave filter device according to claim 12, further comprising:
a first insulating layer on the first main surface and covering the plurality of first electrode fingers and the plurality of first reflective electrode fingers; wherein
in a region, on the first main surface, located in the third direction as viewed from one or more of the second electrode fingers located in the end region, none of the first electrode fingers are provided and the first insulating layer is provided.

15. The acoustic wave filter device according to claim 12, further comprising:
a second insulating layer on the second main surface and covering the plurality of second electrode fingers and the plurality of second reflective electrode fingers; wherein
in a region, on the second main surface, located in the third direction as viewed from one or more of the first reflective electrode fingers located in the end region, none of the second reflective electrode fingers are provided and the second insulating layer is provided.

16. The acoustic wave filter device according to claim 12, further comprising:
a first insulating layer on the first main surface and covering the plurality of first electrode fingers and the plurality of first reflective electrode fingers; wherein
in a region, on the first main surface, located in the third direction as viewed from one or more of the second reflective electrode fingers located in the end region, none of the first reflective electrode fingers are provided and the first insulating layer is provided.

17. The acoustic wave filter device according to claim 12, wherein, in the end region of the inter-reflector region in the first direction, the region in which none of the first electrode fingers and the second electrode fingers face each other in the third direction, and the region in which none of the first reflective electrode fingers and the second reflective electrode fingers face each other in the third direction are provided.

18. The acoustic wave filter device according to claim 17, wherein, in a region, on the second main surface, located in the third direction as viewed from one or more of the first electrode fingers located in the end region, none of the second electrode fingers are provided and one or more of the second reflective electrode fingers are provided.

19. The acoustic wave filter device according to claim 17, wherein, in a region, on the first main surface, located in the third direction as viewed from one or more of the second electrode fingers located in the end region, none of the first electrode fingers are provided and one or more of the first reflective electrode fingers are provided.

20. A multiplexer comprising:
a plurality of filters including the acoustic wave filter device according to claim 12; wherein
one of an input/output terminal and an input/output terminal of each of the plurality of filters is directly or indirectly connected to a common terminal; and
at least one of the plurality of filters excluding the acoustic wave filter device has a passband higher than a frequency in a passband of the acoustic wave filter device.
